(19) United States
(12) Patent Application Publication
(10) Pub. No.: US 2024/0112060 A1
(43) Pub. Date: Apr. 4, 2024

(54) Hardware-Optimized Parity-check (HOP) Gates for Superconducting Surface Codes

(71) Applicants: Rigetti & Co, LLC, Berkeley, CA (US); Goldman Sachs & Co. LLC, New York, NY (US)

(72) Inventors: Matthew J. Reagor, San Rafael, CA (US); Thomas C. Bohdanowicz, Pasadena, CA (US); David Rodriguez Perez, Ketchikan, AK (US); Eyob A. Sete, Walnut Creek, CA (US); William J. Zeng, Berkeley, CA (US)

(73) Assignees: Rigetti & Co, LLC, Berkeley, CA (US); Goldman Sachs & Co. LLC, New York, NY (US)

(21) Appl. No.: 18/465,085

(22) Filed: Sep. 11, 2023

Related U.S. Application Data
(60) Provisional application No. 63/405,219, filed on Sep. 9, 2022.

(51) Int. Cl. G06N 10/70; H03M 13/00; H03M 13/15

(52) U.S. Cl. CPC G06N 10/70; H03M 13/159; H03M 13/611

(57) ABSTRACT

In a general aspect, a surface code syndrome measurement is performed on a superconducting quantum processing unit. In some implementations, the superconducting quantum processing unit is caused to apply a quantum error correction code including X-type and Z-type stabilizer check patches. Each of the X-type and Z-type stabilizer check patches includes a stabilizer check qubit device and data qubit devices of the superconducting quantum processing unit. Applying the quantum error correction code includes iteratively twirling the data qubit devices in a stabilizer check patch; and evolving the stabilizer check qubit device in the stabilizer check patch and the data qubit devices in the stabilizer check patch under an interaction Hamiltonian. The interaction Hamiltonian includes a plurality of terms interactions between the stabilizer check qubit device in the stabilizer check patch and a respective one of the data qubit devices in the stabilizer check patch.

### CROSS-REFERENCE TO RELATED APPLICATIONS

This application claims priority to U.S. Provisional Patent Application No. 63/405,219, filed Sep. 9, 2022, entitled “Hardware Optimized Parity Check Gates for Superconducting Surface Codes.” The above-referenced priority document is incorporated herein by reference in its entirety.

### TECHNICAL FIELD

The following description relates to surface codes using multi-qubit hardware-optimized parity-check gates.

### BACKGROUND

Quantum computers can perform computational tasks by storing and processing information within quantum states of quantum systems. For example, qubits (i.e., quantum bits) can be stored in, and represented by, an effective two-level sub-manifold of a quantum coherent physical system. A variety of physical systems have been proposed for quantum computing applications. Examples include superconducting circuits, trapped ions, spin systems, and others.

### BRIEF DESCRIPTION OF THE DRAWINGS

FIG. 1 is a block diagram of an example computing environment.

FIG. 2A is a schematic diagram showing aspects of an example quantum error correction code layout.

FIG. 2B is a schematic diagram showing aspects of an example quantum logic circuit.

FIG. 3 is a schematic diagram of a top view of an example superconducting quantum processing unit.

FIG. 4A is a schematic diagram showing aspects of example quantum logic circuits and their respective Pauli error models.

FIG. 4B is a plot showing channel weight as a function of Pauli channel for the multi-qubit HOP gate and the standard circuit shown in FIG. 4A.

FIG. 5A is a schematic diagram showing a schedule of surface code operations of a standard syndrome measurement circuit in the example quantum error correction code layout shown in FIG. 2A.

FIG. 5B is a schematic diagram showing a schedule of surface code operations of a HOP syndrome measurement circuit in the example quantum error correction code layout shown in FIG. 2A.

FIG. 6 is a flow chart showing aspects of an example HOP syndrome measurement process.

FIGS. 7-8 include a plot showing logical failure rate in per shot as a function of physical single qubit error rate p₁ at various distance of the standard rotated surface code syndrome measurement circuit shown in FIG. 5A and a plot showing logical failure rate in per shot as a function of physical error rate at various distance of the HOP syndrome measurement circuit and process shown in FIGS. 5B and 6.

FIGS. 9-10 include a plot showing the number of physical qubit devices required and a plot showing the overall space-time volume required as a function of physical error rate for both the standard syndrome measurement circuit shown in FIG. 5A and the HOP syndrome measurement circuit and process shown in FIGS. 5B and 6.

FIGS. 11A-11B include tables showing parameters and values in the numerical diagonalization of the 5-qubit Hamiltonian shown in Equation (2).

FIGS. 12A-12B include a table showing fit parameters obtained from linear regression for the HOP syndrome measurement circuit and process shown in FIGS. 5B and 6 and a table showing fit parameters obtained from linear regression for the standard syndrome measurement circuit shown in FIG. 5A.

FIGS. 13A-13B include a log-log plot showing logical error rate as a function of physical error rate at various distance of the HOP syndrome measurement circuit and process shown in FIGS. 5B and 6 and a log-log plot showing logical error rate as a function of physical error rate at various distances of the standard rotated surface code syndrome measurement circuit shown in FIG. 5A.

### DETAILED DESCRIPTION

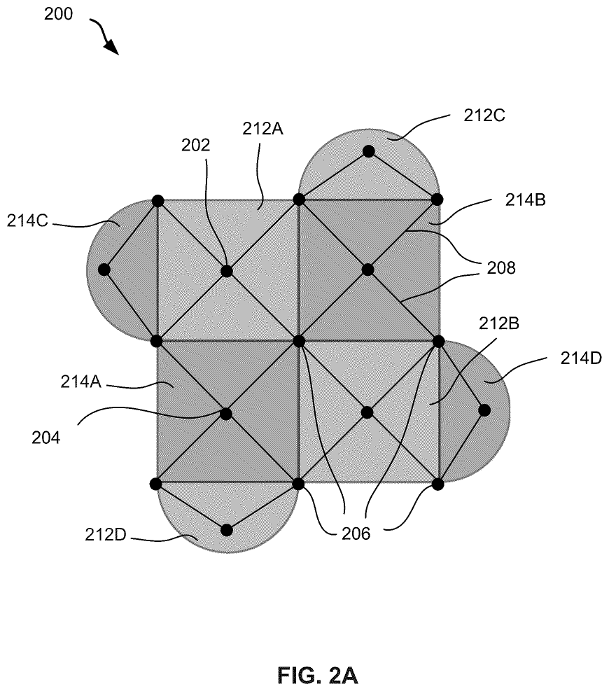

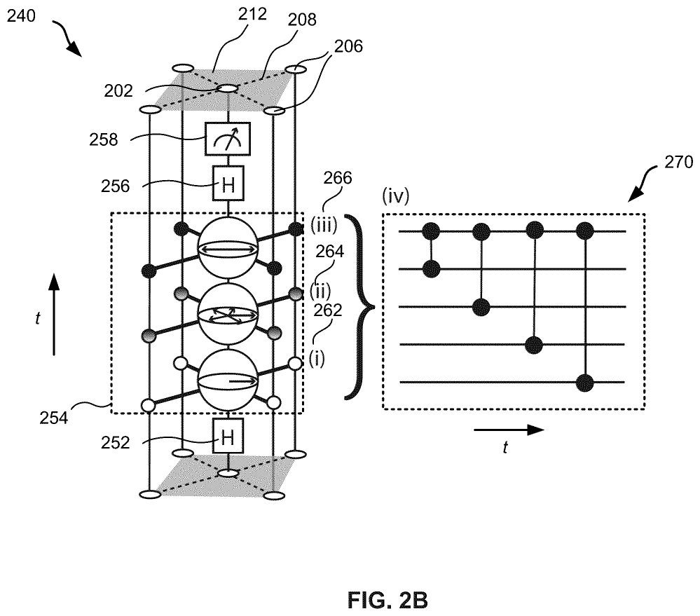

In some aspects of what is described here, an error correcting surface code based on multi-qubit measurements is used to realize fault-tolerant quantum logic steps. In some implementations, a surface code based on multi-body interactions between superconducting transmon qubit devices can achieve stabilizer-type measurements through simultaneous multi-qubit conditional phase accumulation. In some implementations, the surface code includes multi-qubit hardware optimized parity-check (HOP) gates implemented on a superconducting quantum processing unit with planar transmon qubit devices arranged in a square array with one stabilizer check qubit device coupled to four nearest-neighbors data qubit devices via tunable-frequency coupler devices. To operate the superconducting quantum processing unit for error correction, exchange coupling rates and qubit frequencies are tuned to engineer a strong-dispersive ZZ interaction pairwise between data qubit devices and the stabilizer check qubit devices. Evolved over time, the interaction generates a multi-qubit HOP gate, controlled on the data register (e.g., data qubit devices 206, 302, 510 as shown in FIGS. 2, 3 and 5) and targeting a qubit defined by a local stabilizer check qubit device—mapping the odd and even parity states of the data register onto two states of the stabilizer check qubit device. The stabilizer check qubit device can be measured; and the associated error syndrome can be recorded.

In some implementations, the systems and techniques described here can provide and/or facilitate technical advantages and improvements. The methods and techniques presented here may enable a superconducting processing unit that are capable of achieving different error profiles and performing efficient stabilizer quantum error correction. The methods and techniques presented here can, in some cases, reduce the requirements for fault-tolerance while taking advantage of the investment towards machines for near-term quantum applications. The methods and techniques presented here based on the HOP syndrome measurement circuit can reduce the system calibration problem to a single gate per check, have error correction advantages for near-term machines due to a higher threshold, and reduce physical overhead. In some implementations, the HOP-based surface code enables efficient heat management in large-scale superconducting processing unit, reduces passive and active heat load at the lowest-temperature stages of the dilution refrigerator, and thus the total thermal budget. The HOP-based surface code allows for an equal thermal footprint while doubling the number of physical qubit devices. In some cases, a combination of these and potentially other advantages and improvements may be obtained.

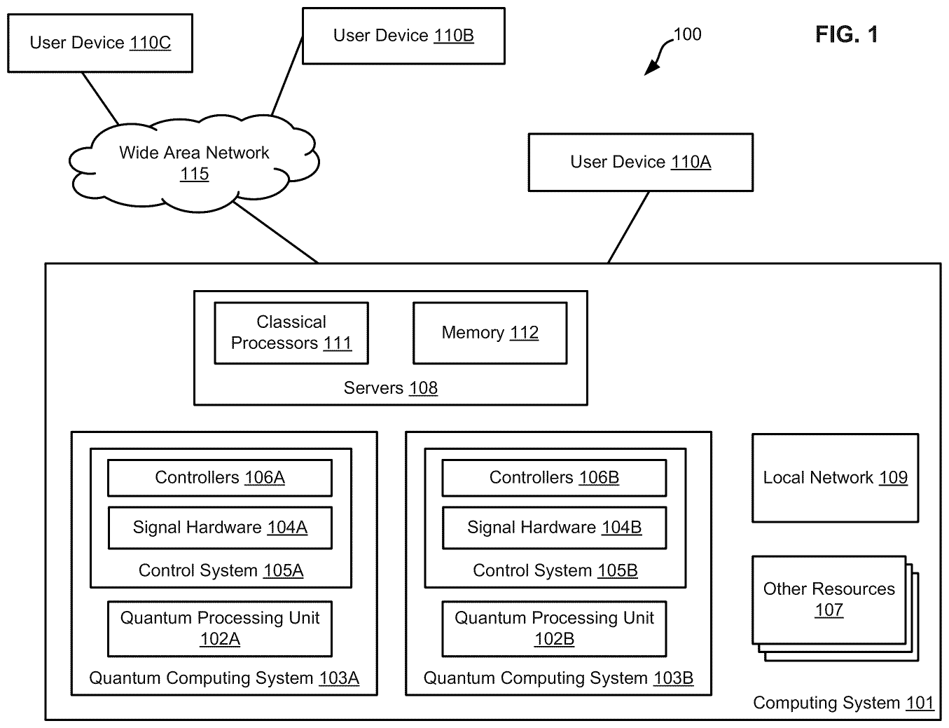

FIG. 1 is a block diagram of an example computing environment 100. The example computing environment 100 shown in FIG. 1 includes a computing system 101 and user devices 110A, 110B, 110C. A computing environment may include additional or different features, and the components of a computing environment may operate as described with respect to FIG. 1 or in another manner.

The example computing system 101 includes classical and quantum computing resources and exposes their functionality to the user devices 110A, 110B, 110C (referred to collectively as “user devices 110”). The computing system 101 shown in FIG. 1 includes one or more servers 108, quantum computing systems 103A, 103B, a local network 109, and other resources 107. The computing system 101 may also include one or more user devices (e.g., the user device 110A) as well as other features and components. A computing system may include additional or different features, and the components of a computing system may operate as described with respect to FIG. 1 or in another manner.

The example computing system 101 can provide services to the user devices 110, for example, as a cloud-based or remote-accessed computer system, as a distributed computing resource, as a supercomputer or another type of high-performance computing resource, or in another manner. The computing system 101 or the user devices 110 may also have access to one or more other quantum computing systems (e.g., quantum computing resources that are accessible through the wide area network 115, the local network 109, or otherwise).

The user devices 110 shown in FIG. 1 may include one or more classical processors, memory, user interfaces, communication interfaces, and other components. For instance, the user devices 110 may be implemented as laptop computers, desktop computers, smartphones, tablets, or other types of computer devices. In the example shown in FIG. 1, to access computing resources of the computing system 101, the user devices 110 send information (e.g., programs, instructions, commands, requests, input data, etc.) to the servers 108; and in response, the user devices 110 receive information (e.g., application data, output data, prompts, alerts, notifications, results, etc.) from the servers 108. The user devices 110 may access services of the computing system 101 in another manner, and the computing system 101 may expose computing resources in another manner.

In the example shown in FIG. 1, the local user device 110A operates in a local environment with the servers 108 and other elements of the computing system 101. For instance, the user device 110A may be co-located with (e.g., located within 0.5 to 1 km of) the servers 108 and possibly other elements of the computing system 101. As shown in FIG. 1, the user device 110A communicates with the servers 108 through a local data connection.

The local data connection in FIG. 1 is provided by the local network 109. For example, some or all of the servers 108, the user device 110A, the quantum computing systems 103A, 103B, and the other resources 107 may communicate with each other through the local network 109. In some implementations, the local network 109 operates as a communication channel that provides one or more low-latency communication pathways from the server 108 to the quantum computing systems 103A, 103B (or to one or more of the elements of the quantum computing systems 103A, 103B). The local network 109 can be implemented, for instance, as a wired or wireless Local Area Network, an Ethernet connection, or another type of wired or wireless connection. The local network 109 may include one or more wired or wireless routers, wireless access points (WAPs), wireless mesh nodes, switches, high-speed cables, or a combination of these and other types of local network hardware elements. In some cases, the local network 109 includes a software-defined network that provides communication among virtual resources, for example, among an array of virtual machines operating on the server 108 and possibly elsewhere.

In the example shown in FIG. 1, the remote user devices 110B, 110C operate remote from the servers 108 and other elements of the computing system 101. For instance, the user devices 110B, 110C may be located at a remote distance (e.g., more than 1 km, 10 km, 100 km, 1,000 km, 10,000 km, or farther) from the servers 108 and possibly other elements of the computing system 101. As shown in FIG. 1, each of the user devices 110B, 110C communicates with the servers 108 through a remote data connection.

The remote data connection in FIG. 1 is provided by a wide area network 115, which may include, for example, the Internet or another type of wide area communication network. In some cases, remote user devices use another type of remote data connection (e.g., satellite-based connections, a cellular network, a virtual private network, etc.) to access the servers 108. The wide area network 115 may include one or more internet servers, firewalls, service hubs, base stations, or a combination of these and other types of remote networking elements. Generally, the computing environment 100 can be accessible to any number of remote user devices.

The example servers 108 shown in FIG. 1 can manage interaction with the user devices 110 and utilization of the quantum and classical computing resources in the computing system 101. For example, based on information from the user devices 110, the servers 108 may delegate computational tasks to the quantum computing systems 103A, 103B and the other resources 107; the servers 108 can then send information to the user devices 110 based on output data from the computational tasks performed by the quantum computing systems 103A, 103B, and the other resources 107.

As shown in FIG. 1, the servers 108 are classical computing resources that include classical processors 111 and memory 112. The servers 108 may also include one or more communication interfaces that allow the servers to communicate via the local network 109, the wide area network 115, and possibly other channels. In some implementations, the servers 108 may include a host server, an application server, a virtual server, or a combination of these and other types of servers. The servers 108 may include additional or different features, and may operate as described with respect to FIG. 1 or in another manner.

The classical processors 111 can include various kinds of apparatus, devices, and machines for processing data, including, by way of example, a microprocessor, a central processing unit (CPU), a graphics processing unit (GPU), an FPGA (field programmable gate array), an ASIC (application specific integrated circuit), or combinations of these. The memory 112 can include, for example, a random-access memory (RAM), a storage device (e.g., a writable read-only memory (ROM) or others), a hard disk, or another type of storage medium. The memory 112 can include various forms of volatile or non-volatile memory, media, and memory devices, etc.

Each of the example quantum computing systems 103A, 103B operates as a quantum computing resource in the computing system 101. The other resources 107 may include additional quantum computing resources (e.g., quantum computing systems, quantum simulators, or both) as well as classical (non-quantum) computing resources such as, for example, digital microprocessors, specialized co-processor units (e.g., graphics processing units (GPUs), cryptographic co-processors, etc.), special purpose logic circuitry (e.g., field programmable gate arrays (FPGAs), application-specific integrated circuits (ASICs), etc.), systems-on-chips (SoCs), etc., or combinations of these and other types of computing modules.

In some implementations, the servers 108 generate programs, identify appropriate computing resources (e.g., a QPU or QVM) in the computing system 101 to execute the programs, and send the programs to the identified resources for execution. For example, the servers 108 may send programs to the quantum computing system 103A, the quantum computing system 103B, or any of the other resources 107. The programs may include classical programs, quantum programs, hybrid classical/quantum programs, and may include any type of function, code, data, instruction set, etc.

In some instances, programs can be formatted as source code that can be rendered in human-readable form (e.g., as text) and can be compiled, for example, by a compiler running on the servers 108, on the quantum computing systems 103, or elsewhere. In some instances, programs can be formatted as compiled code, such as, for example, binary code (e.g., machine-level instructions) that can be executed directly by a computing resource. Each program may include instructions corresponding to computational tasks that, when performed by an appropriate computing resource, generate output data based on input data. For example, a program can include instructions formatted for a quantum computer system, a simulator, a digital microprocessor, co-processor or other classical data processing apparatus, or another type of computing resource.

In some cases, a program may be expressed in a hardware-independent format. For example, quantum machine instructions may be provided in a quantum instruction language such as Quil, described in the publication “A Practical Quantum Instruction Set Architecture,” arXiv:1608.03355v2, dated Feb. 17, 2017, or another quantum instruction language. For instance, the quantum machine instructions may be written in a format that can be executed by a broad range of quantum processing units or simulators. In some cases, a program may be expressed in high-level terms of quantum logic gates or quantum algorithms, in lower-level terms of fundamental qubit rotations and controlled rotations, or in another form. In some cases, a program may be expressed in terms of control signals (e.g., pulse sequences, delays, etc.) and parameters for the control signals (e.g., frequencies, phases, durations, channels, etc.). In some cases, a program may be expressed in another form or format. In some cases, a program may utilize Quil-T, described in the publication “Gain deeper control of Rigetti quantum processing units with Quil-T,” available at https://medium.com/rigetti/gain-deeper-control-of-rigetti-quantum-processors-with-quil-t-ea8945061e5b dated Dec. 10, 2020, which is hereby incorporated by reference in the present disclosure.

In some implementations, the servers 108 include one or more compilers that convert programs between formats. For example, the servers 108 may include a compiler that converts hardware-independent instructions to binary programs for execution by the quantum computing systems 103A, 103B. In some cases, a compiler can compile a program to a format that targets a specific quantum resource in the computer system 101. For example, a compiler may generate a different binary program (e.g., from the same source code) depending on whether the program is to be executed by the quantum computing system 103A or the quantum computing system 103B.

In some cases, a compiler generates a partial binary program that can be updated, for example, based on specific parameters. For instance, if a quantum program is to be executed iteratively on a quantum computing system with varying parameters on each iteration, the compiler may generate the binary program in a format that can be updated with specific parameter values at runtime (e.g., based on feedback from a prior iteration, or otherwise); the parametric update can be performed without further compilation. In some cases, a compiler generates a full binary program that does not need to be updated or otherwise modified for execution.

In some implementations, the servers 108 generate a schedule for executing programs, allocate computing resources in the computing system 101 according to the schedule, and delegate the programs to the allocated computing resources. The servers 108 can receive, from each computing resource, output data from the execution of each program. Based on the output data, the servers 108 may generate additional programs that are then added to the schedule, output data that is provided back to a user device 110, or perform another type of action.

In some implementations, all or part of the computing system 101 operates as a hybrid computing environment. For example, quantum programs can be formatted as hybrid classical/quantum programs that include instructions for execution by one or more quantum computing resources and instructions for execution by one or more classical resources. The servers 108 can allocate quantum and classical computing resources in the hybrid computing environment, and delegate programs to the allocated computing resources for execution. The quantum computing resources in the hybrid environment may include, for example, one or more quantum processing units (QPUs), one or more quantum virtual machines (QVMs), one or more quantum simulators, or possibly other types of quantum resources. The classical computing resources in the hybrid environment may include, for example, one or more digital microprocessors, one or more specialized co-processor units (e.g., graphics processing units (GPUs), cryptographic co-processors, etc.), special purpose logic circuitry (e.g., field programmable gate arrays (FPGAs), application-specific integrated circuits (ASICs), etc.), systems-on-chips (SoCs), or other types of computing modules.

In some cases, the servers 108 can select the type of computing resource (e.g., quantum or classical) to execute an individual program, or part of a program, in the computing system 101. For example, the servers 108 may select a particular quantum processing unit (QPU) or other computing resource based on availability of the resource, speed of the resource, information or state capacity of the resource, a performance metric (e.g., process fidelity) of the resource, or based on a combination of these and other factors. In some cases, the servers 108 can perform load balancing, resource testing and calibration, and other types of operations to improve or optimize computing performance.

Each of the example quantum computing systems 103A, 103B shown in FIG. 1 can perform quantum computational tasks by executing quantum machine instructions (e.g., a binary program compiled for the quantum computing system). In some implementations, a quantum computing system can perform quantum computation by storing and manipulating information within quantum states of a composite quantum system. For example, qubits (i.e., quantum bits) can be stored in, and represented by, an effective two-level sub-manifold of a quantum coherent physical system. In some instances, quantum logic can be executed in a manner that allows large-scale entanglement within the quantum system. Control signals can manipulate the quantum states of individual qubits and the joint states of multiple qubits. In some instances, information can be read out from the composite quantum system by measuring the quantum states of the qubits. In some implementations, the quantum states of the qubits are read out by measuring the transmitted or reflected signal from auxiliary quantum devices that are coupled to individual qubits.

In some implementations, a quantum computing system can operate using gate-based models for quantum computing. For example, the qubits can be initialized in an initial state, and a quantum logic circuit comprised of a series of quantum logic gates can be applied to transform the qubits and extract measurements representing the output of the quantum computation. Individual qubits may be controlled by single-qubit quantum logic gates, and pairs of qubits may be controlled by two-qubit quantum logic gates (e.g., entangling gates that are capable of generating entanglement between the pair of qubits). In some implementations, a quantum computing system can operate using adiabatic or annealing models for quantum computing. For instance, the qubits can be initialized in an initial state, and the controlling Hamiltonian can be transformed adiabatically by adjusting control parameters to another state that can be measured to obtain an output of the quantum computation.

In some models, fault-tolerance can be achieved by applying a set of high-fidelity control and measurement operations to the qubits. For example, quantum error correcting codes can be deployed to achieve fault-tolerant quantum computation. Other computational regimes may be used; for example, quantum computing systems may operate in non-fault-tolerant regimes. In some implementations, a quantum computing system is constructed and operated according to a scalable quantum computing architecture. For example, in some cases, the architecture can be scaled to a large number of qubits to achieve large-scale general purpose coherent quantum computing. Other architectures may be used; for example, quantum computing systems may operate in small-scale or non-scalable architectures.

The example quantum computing system 103A shown in FIG. 1 includes a quantum processing unit 102A and a control system 105A, which controls the operation of the quantum processing unit 102A. Similarly, the example quantum computing system 103B includes a quantum processing unit 102B and a control system 105B, which controls the operation of a quantum processing unit 102B. A quantum computing system may include additional or different features, and the components of a quantum computing system may operate as described with respect to FIG. 1 or in another manner.

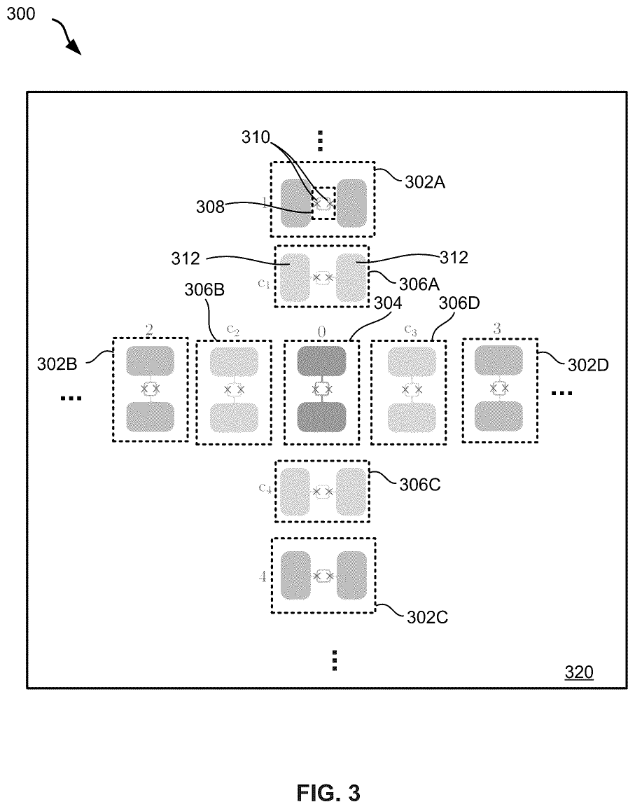

In some instances, all or part of the quantum processing unit 102A functions as a quantum processing unit, a quantum memory, or another type of subsystem. In some examples, the quantum processing unit 102A includes a superconducting quantum circuit system. The superconducting quantum circuit may include data qubit devices, stabilizer check qubit devices, coupler devices, readout devices, and possibly other devices that are used to store and process quantum information. In some cases, multiple data qubit devices are operatively coupled to a single stabilizer check qubit device through respective coupler devices. In some implementations, the quantum processing unit 102A is implemented as the quantum processing unit 300 shown in FIG. 3 or in another manner. In certain examples, the qubit devices and the coupler devices are implemented as superconducting quantum circuit devices that include Josephson junctions, for example, in Superconducting QUantum Interference Device (SQUID) loops or other arrangements, and are controlled by radio-frequency signals, microwave signals, and bias signals delivered to the quantum processing unit 102A.

In some instances, the quantum processing modules can include a superconducting quantum circuit that includes one or more quantum circuit devices. For instance, a superconducting quantum circuit may include qubit devices, readout resonator devices, Josephson junctions, or other quantum circuit devices. In some implementations, quantum circuit devices in a quantum processing unit can be collectively operated to define a single logical qubit. A logical qubit comprises a quantum register, for instance multiple physical qubits or qudits, and associated circuitry, that supports physical operations which can be used to detect or correct errors associated with logical states in a quantum algorithm. Physical operations supported by the quantum register associated with a logical qubit may include single-qubit or multi-qubit quantum logic gates and readout mechanisms. Error detection or correction mechanisms associated with a logical qubit may be based on quantum error correction schemes such as the surface code, color code, Bacon-Shor codes, low-density parity check codes (LDPC), some combination of these, or others.

In some implementations, a quantum error correction code based on multi-qubit hardware-optimized parity-check (HOP) gates is implemented on the quantum processing unit. In some implementations, a multi-qubit HOP gate is a single stabilizer check operation defined by strong, multi-qubit dispersive ZZ interactions between multiple data qubit devices and a stabilizer check qubit device. As used herein in this context, the term “strong” may refer in some cases to 1 MHz of coupling or more. Additionally or alternatively, the term “strong” in the context of multi-qubit dispersive ZZ interactions may refer to a rate that is 10 times or more than the rate of a single qubit decoherence as may be typical. The multi-qubit HOP gate (e.g., the HOP gate 254 in FIG. 2B) including a series of sub-operations is logically equivalent to a series of CZ or CX gates (e.g., the quantum logic circuit 270 in FIG. 2B).

The quantum processing unit 102A may include, or may be deployed within, a controlled environment. The controlled environment can be provided, for example, by shielding equipment, cryogenic equipment, and other types of environmental control systems. In some examples, the components in the quantum processing unit 102A operate in a cryogenic temperature regime and are subject to very low electromagnetic and thermal noise. For example, magnetic shielding can be used to shield the system components from stray magnetic fields, optical shielding can be used to shield the system components from optical noise, thermal shielding and cryogenic equipment can be used to maintain the system components at controlled temperature, etc.

In some implementations, the example quantum processing unit 102A can process quantum information by applying control signals to the qubits in the quantum processing unit 102A. The control signals can be configured to encode information in the qubits, to process the information by performing quantum logic gates or other types of operations, or to extract information from the qubits. In some examples, the operations can be expressed as single-qubit quantum logic gates, two-qubit quantum logic gates, or other types of quantum logic gates that operate on one or more qubits. A quantum logic circuit, which includes a sequence of quantum logic operations, can be applied to the qubits to perform a quantum algorithm. The quantum algorithm may correspond to a computational task, a hardware test, a quantum error correction procedure, a quantum state distillation procedure, or a combination of these and other types of operations.

The example control system 105A includes controllers 106A and signal hardware 104A. Similarly, control system 105B includes controllers 106B and signal hardware 104B. All or part of the control systems 105A, 105B can operate in a room-temperature environment or another type of environment, which may be located near the respective quantum processing units 102A, 102B. In some cases, the control systems 105A, 105B include classical computers, signaling equipment (microwave, radio, optical, bias, etc.), electronic systems, vacuum control systems, refrigerant control systems, or other types of control systems that support operation of the quantum processing units 102A, 102B.

The control systems 105A, 105B may be implemented as distinct systems that operate independent of each other. In some cases, the control systems 105A, 105B may include one or more shared elements; for example, the control systems 105A, 105B may operate as a single control system that operates both quantum processing units 102A, 102B. Moreover, a single quantum computing system may include multiple quantum processing units, which may operate in the same controlled (e.g., cryogenic) environment or in separate environments.

The example signal hardware 104A includes components that communicate with the quantum processing unit 102A. The signal hardware 104A may include, for example, waveform generators, amplifiers, digitizers, high-frequency sources, DC sources, AC sources, etc. The signal hardware may include additional or different features and components. In the example shown, components of the signal hardware 104A are adapted to interact with the quantum processing unit 102A. For example, the signal hardware 104A can be configured to operate in a particular frequency range, configured to generate and process signals in a particular format, or the hardware may be adapted in another manner.

In some instances, one or more components of the signal hardware 104A generate control signals, for example, based on control information from the controllers 106A. The control signals can be delivered to the quantum processing unit 102A during operation of the quantum computing system 103A. For instance, the signal hardware 104A may generate signals to implement quantum logic operations, readout operations, or other types of operations. As an example, the signal hardware 104A may include arbitrary waveform generators (AWGs) that generate electromagnetic waveforms (e.g., microwave or radiofrequency) or laser systems that generate optical waveforms. The waveforms or other types of signals generated by the signal hardware 104A can be delivered to devices in the quantum processing unit 102A to operate qubit devices, readout devices, bias devices, coupler devices, or other types of components in the quantum processing unit 102A.

In some instances, the signal hardware 104A receives and processes signals from the quantum processing unit 102A. The received signals can be generated by the execution of a quantum program on the quantum computing system 103A. For instance, the signal hardware 104A may receive signals from the devices in the quantum processing unit 102A in response to readout or other operations performed by the quantum processing unit 102A. Signals received from the quantum processing unit 102A can be mixed, digitized, filtered, or otherwise processed by the signal hardware 104A to extract information, and the information extracted can be provided to the controllers 106A or handled in another manner. In some examples, the signal hardware 104A may include a digitizer that digitizes electromagnetic waveforms (e.g., microwave or radiofrequency) or optical signals, and a digitized waveform can be delivered to the controllers 106A or to other signal hardware components. In some instances, the controllers 106A process the information from the signal hardware 104A and provide feedback to the signal hardware 104A; based on the feedback, the signal hardware 104A can in turn generate new control signals that are delivered to the quantum processing unit 102A.

In some implementations, the signal hardware 104A includes signal delivery hardware that interfaces with the quantum processing unit 102A. For example, the signal hardware 104A may include filters, attenuators, directional couplers, multiplexers, diplexers, bias components, signal channels, isolators, amplifiers, power dividers, and other types of components. In some instances, the signal delivery hardware performs preprocessing, signal conditioning, or other operations to the control signals to be delivered to the quantum processing unit 102A. In some instances, signal delivery hardware performs preprocessing, signal conditioning, or other operations on readout signals received from the quantum processing unit 102A.

The example controllers 106A communicate with the signal hardware 104A to perform control operation of the quantum computing system 103A. The controllers 106A may include classical computing hardware that directly interfaces with components of the signal hardware 104A. The example controllers 106A may include classical processors, memory, clocks, digital circuitry, analog circuitry, and other types of systems or subsystems. The classical processors may include one or more single- or multi-core microprocessors, digital electronic controllers, special purpose logic circuitry, e.g., an FPGA (field programmable gate array) or an ASIC (application specific integrated circuit), or other types of data processing apparatus. The memory may include any type of volatile or non-volatile memory or another type of computer storage medium. The controllers 106A may also include one or more communication interfaces that allow the controllers 106A to communicate via the local network 109 and possibly other channels. The controllers 106A may include additional or different features and components.

In some implementations, the controllers 106A include memory or other components that store quantum state information, for example, based on qubit readout operations performed by the quantum computing system 103A. For instance, the states of one or more qubits in the quantum processing unit 102A can be measured by qubit readout operations, and the measured state information can be stored in a cache or other type of memory system in one or more of the controllers 106A. In some cases, the measured state information is subsequently used in the execution of a quantum program, a quantum error correction procedure, a quantum processing unit (QPU) calibration or testing procedure, or another type of quantum process.

In some implementations, the controllers 106A include memory or other components that store a quantum program containing quantum machine instructions for execution by the quantum computing system 103A. In some instances, the controllers 106A can interpret the quantum machine instructions and perform hardware-specific control operations according to the quantum machine instructions. For example, the controllers 106A may cause the signal hardware 104A to generate control signals that are delivered to the quantum processing unit 102A to execute the quantum machine instructions.

In some instances, the controllers 106A extract qubit state information from qubit readout signals, for example, to identify the quantum states of qubits in the quantum processing unit 102A or for other purposes. For example, the controllers may receive the qubit readout signals (e.g., in the form of analog waveforms) from the signal hardware 104A, digitize the qubit readout signals, and extract qubit state information from the digitized signals. In some cases, the controllers 106A compute measurement statistics based on qubit state information from multiple shots of a quantum program. For example, each shot may produce a bitstring representing qubit state measurements for a single execution of the quantum program, and a collection of bitstrings from multiple shots may be analyzed to compute quantum state probabilities.

In some implementations, the controllers 106A include one or more clocks that control the timing of operations. For example, operations performed by the controllers 106A may be scheduled for execution over a series of clock cycles, and clock signals from one or more clocks can be used to control the relative timing of each operation or groups of operations. In some implementations, the controllers 106A may include classical computer resources that perform some or all of the operations of the servers 108 described above. For example, the controllers 106A may operate a compiler to generate binary programs (e.g., full or partial binary programs) from source code; the controllers 106A may include an optimizer that performs classical computational tasks of a hybrid classical/quantum program; the controllers 106A may update binary programs (e.g., at runtime) to include new parameters based on an output of the optimizer, etc.

The other quantum computing system 103B and its components (e.g., the quantum processing unit 102B, the signal hardware 104B, and controllers 106B) can be implemented as described above with respect to the quantum computing system 103A; in some cases, the quantum computing system 103B and its components may be implemented or may operate in another manner.

In some implementations, the quantum computing systems 103A, 103B are disparate systems that provide distinct modalities of quantum computation. For example, the computer system 101 may include both an adiabatic quantum computing system and a gate-based quantum computer system. As another example, the computer system 101 may include a superconducting circuit-based quantum computing system and an ion trap-based quantum computer system. In such cases, the computer system 101 may utilize each quantum computing system according to the type of quantum program that is being executed, according to availability or capacity, or based on other considerations.

FIG. 2A is a schematic diagram showing aspects of an example quantum error correction code layout 200. As shown in FIG. 2A, the example quantum error correction code layout 200 includes patches of quantum error correcting codes defined on a 2D lattice of qubit devices of a quantum processing unit. For example, the quantum error correcting codes can be surface codes depending on the physical/logical error rates. In certain examples, the quantum error correcting codes can be other error correcting codes, including those with two-dimensional connectivity graphs, such as 2D color codes. Square patches in FIG. 2A represent different patterns of stabilizer checks. For instance, square patches 212A, 212B, 212C, 212D are Z-type stabilizer patches of rotated surface codes with Z-type stabilizer checks and square patches 214A, 214B, 214C, 214D are X-type stabilizer patches of rotated surface codes with X-type stabilizer checks. The half circle patches are weight-two X-type or Z-type stabilizer check patches (e.g., ZZ or XX checks), which are generated by weight-three HOP gates. A weight-three HOP gate is a gate with one stabilizer check qubit device and two data qubit devices; and a weight-five HOP gate is a gate with one stabilizer check qubit device and four data qubit devices.

In some implementations, the quantum processing unit on which the layout 200 applied includes a superconducting quantum circuit which is patterned and fabricated on a singulated substrate. In some instances, the quantum processing unit can be implemented as the example superconducting quantum processing unit 300 as shown in FIG. 3 or in another manner. Each square tile includes a stabilizer check qubit device 202, 204 at the center of a square tile communicably coupled to four data qubit devices 206 at the vertices of the same tile. In certain examples, the stabilizer check qubit device and the data check qubit devices in a square tile may be implemented as the tunable-frequency qubit devices 302, 304 of the superconducting quantum processing unit 300 in FIG. 3 or in another manner.

FIG. 2B is a schematic diagram showing aspects of an example quantum logic circuit 240. In some implementations, the example quantum logic circuit 240 with time proceeding from bottom to top may include additional and different features or components, and components of the example quantum logic circuit 240 may be implemented in another manner. It is to be appreciated that the measurement results can be fed-forward into the next round of stabilizer checks to, in some cases, improve the performance of the system. Dashed lines in the square tile 212 represent connections 208 indicating the presence of pairwise dispersive ZZ interaction between the stabilizer check qubit device 202 located at the center of the square tile 212, and the four data qubit devices 206 located at the vertices of the square tile 212.

As shown in FIG. 2B, the example quantum logic circuit 240 includes a sequence of quantum logic operations is configured for performing a Z-check protocol performed on the square tile 212. In some implementations, the Z-check protocol represented by the quantum logic circuit 240 includes an unconditional Hadamard gate 252 applied to a qubit defined by the stabilizer check qubit device 202 preparing the qubit along the X-axis of its Bloch sphere. The quantum logic circuit 240 further includes a HOP gate 254 applied on qubits defined by the stabilizer check qubit device 202 and the data qubit devices 206 within the square tile 202. In some implementations, a multi-qubit HOP gate includes a stabilizer check operation defined by a strong, multi-qubit dispersive ZZ interaction between the data qubit devices 206 and the stabilizer check qubit device 202.

The HOP gate 254 is applied to the five-qubit system and the five-qubit system is evolved under the interaction Hamiltonian accumulates the desired phase gate. In some implementations, the HOP gate 254 includes sub-operation 262 where no entanglement is present; sub-operation 264 where phases collapse, and sub-operation 266 where register parity mapped to the ±X states of the stabilizer check qubit device 202. The time evolution (operations 262, 264, 266) is logically equivalent to a quantum logic circuit 270 with four CZ gates as shown in (iv) with time proceeding from left to right. Finally, the quantum logic circuit 240 includes a second unconditional Hadamard gate 256, which is applied on the qubit defined by the stabilizer check qubit device 244 and rotates the qubit to the measurement Z basis. In some implementations, a quantum logic circuit representing an X-check protocol is equivalent up to additional Hadamard gates on the qubits defined by the data qubit devices 206 before and after the sequence of quantum logic operations of the quantum logic circuit 240 for the Z-check protocol.

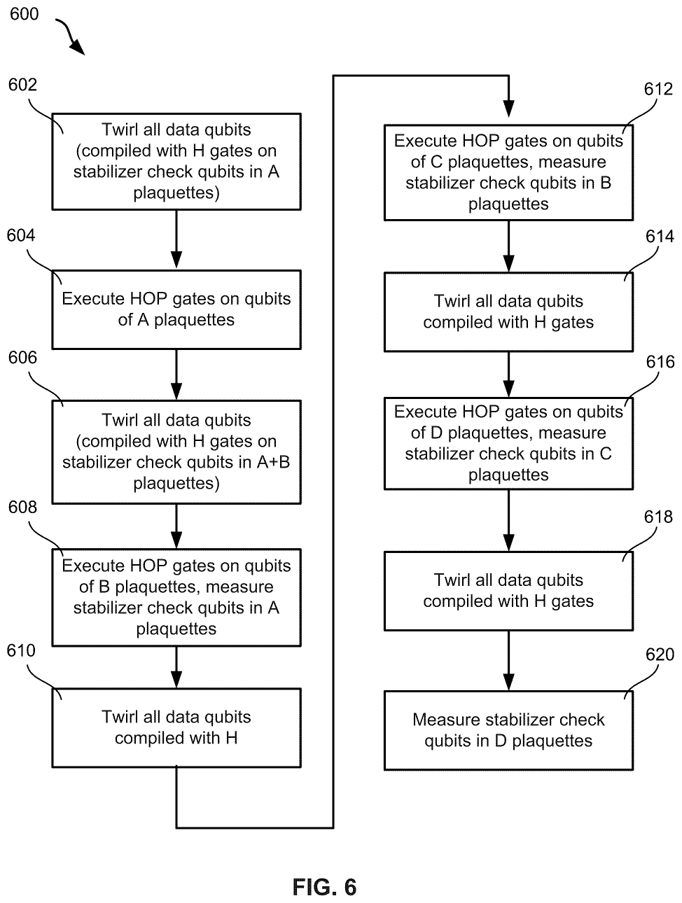

FIG. 3 is a schematic diagram of a top view of an example superconducting quantum processing unit 300. The example superconducting quantum processing unit 300 includes a superconducting quantum circuit with quantum circuit devices. As shown in FIG. 3, the superconducting quantum circuit devices in the example superconducting quantum processing unit 300 include first tunable-frequency qubit devices 302A, 302B, 302C, 302D, and a second tunable-frequency qubit device 304 communicably coupled to the first tunable-frequency qubit devices 302A, 302B, 302C, 302D through respective tunable-frequency coupler devices 306A, 306B, 306C, 306D. Each of the first tunable-frequency qubit devices 302A, 302B, 302C, 302D may be implemented as the data qubit devices 206; the second tunable-frequency qubit device 304 may be implemented as the stabilizer check qubit device 202; and each of the tunable-frequency coupler devices 306A, 306B, 306C, 306D may be implemented as the connection 208 between the data qubit devices and the stabilizer check qubit device. In some implementations, the example superconducting quantum processing unit 300 represents a 5-qubit system which can be used for a single-operation multi-qubit stabilizer check measurement (e.g., the Z-check protocol in FIG. 2B and the HOP syndrome measurement circuit 600 shown in FIG. 6).

In some examples, the first, second tunable-frequency qubit devices 302, 304 and the tunable-frequency coupler devices 306 may be implemented by other types of systems, and the features and components represented in FIG. 3 can be extended in a larger two-dimensional or three-dimensional array of devices. For example, each of the first tunable-frequency qubit devices 302A, 302B, 302C, 302D may be further coupled to a distinct second tunable-frequency qubit device through a distinct tunable-frequency coupler device. The example superconducting quantum processing unit 300 may include additional or different features and components, which may be configured in another manner. For example, the superconducting quantum circuit devices may include respective readout resonator devices associated with the second tunable-frequency qubit devices 304 for performing readout operations. For another example, the example superconducting quantum processing unit 300 may include control lines (e.g., flux bias control lines and/or XY qubit control lines) that a control system (e.g., the control system 105A,B shown in FIG. 1) for providing control signals to first and second tunable-frequency qubit devices and the tunable-frequency coupler devices (e.g., to activate or deactivate coupling between the first and second tunable-frequency qubit devices 302, 304) and performing two-qubit entangling gates, multi-qubit HOP gates or other types of quantum logic operations, such as apply additional gates for tailoring the physical noise for syndrome extraction (e.g., additional random single-qubit Pauli gates that twirl entangling operations), and process the results of the stabilizer checks (e.g., applying a decoder, to inform corrections and/or apply corrections to data qubits or other elements).

In the example quantum processing unit 300 shown in FIG. 3, each of the qubit devices 302, 304 can be encoded with a single bit of quantum information (a qubit). Each of the qubit devices has two eigenstates that are used as computational basis states, and each qubit device can transition between its computational basis states or exist in an arbitrary superposition of its computational basis states. In some examples, a multi-level quantum system, e.g., a qudit, may be a two-level quantum system which includes two lowest energy levels (e.g., the ground state |0 [symbol] and a first excited state |1 [symbol] ) used as computational basis states for quantum computation. In some examples, a multi-level quantum system includes higher energy levels (e.g., a second excited state |2 [symbol] or a third excited state |3 [symbol] ) used as computational basis states for quantum computation in some instances.

Each of the first and second tunable-frequency qubit devices 302, 304 and the tunable-frequency coupler device 306 includes a superconducting circuit loop 308 that has two Josephson junctions 310 connected in parallel. In some implementations, each of the superconducting circuit loops can be inductively coupled to (has a mutual inductance with) a respective control line, which can individually tune a magnetic flux in a respective superconducting circuit loop. The control lines are connected to an external control system (e.g., the control system 105 in FIG. 1) which is configured to generate respective flux control signals. The two Josephson junctions 310 in a superconducting circuit loop 308 include an asymmetric Superconducting Quantum Interference Device (SQUID). In some instances, the first and second tunable-frequency qubit devices 302, 304 and the tunable-frequency coupler device 306 may include additional or different features, and may operate as described with respect to FIG. 3 or in another manner. For example, the superconducting circuit loops 308 may include more than two Josephson junctions or may be configured in another manner.

As shown in FIG. 3, each of the first and second tunable-frequency qubit devices 302, 304 and the tunable-frequency coupler devices 306 includes a pair of electrodes 312. Each pair of electrodes 312 is electrically floating at a certain potential without being conductively connected to a ground plane. In other words, the electrodes 312 are capacitively coupled to the ground plane. In this case, each of the first and second tunable-frequency qubit devices 302, 304 and the tunable-frequency coupler devices 306 is floating. In certain instances, each of the first and second tunable-frequency qubit devices 302, 304 and the tunable-frequency coupler devices 306 can be grounded, e.g., one of the electrodes 312 is galvanically connected to the ground plane.

In some examples, a shunt capacitor can be formed between two electrodes 312 from the same superconducting quantum circuit device. In some instances, a residual capacitor can be formed between two electrodes 312 from two distinct superconducting quantum circuit devices forming a capacitive coupling between the two distinct superconducting quantum circuit devices. In particular, a residual capacitor can be formed between an electrode 312 of a tunable-frequency coupler device 306 and an electrode 312 of the first or second tunable-frequency qubit devices 302, 304. In some instances, a residual capacitor can be formed between an electrode 312 of the first tunable-frequency qubit device 302 and an electrode 312 of the second tunable-frequency qubit device 304.

The example superconducting quantum processing unit 300 shown in FIG. 3 resides on the top surface of a substrate 320. In certain instances, the substrate 320 may be an elemental semiconductor, for example silicon (Si), germanium (Ge), selenium (Se), tellurium (Te), or another elemental semiconductor. In some instances, the substrate 320 may also include a compound semiconductor such as aluminum oxide (sapphire), silicon carbide (SiC), gallium arsenic (GaAs), indium arsenide (InAs), indium phosphide (InP), silicon germanium (SiGe), silicon germanium carbide (SiGeC), gallium arsenic phosphide (GaAsP), gallium indium phosphide (GaInP), or another compound semiconductor. In some instances, the substrate 320 may also include a superlattice with elemental or compound semiconductor layers. In certain instances, the substrate 320 includes an epitaxial layer. In some examples, the substrate 320 may have an epitaxial layer overlying a bulk semiconductor or may include a semiconductor-on-insulator (SOI) structure.

The superconducting quantum circuit of the superconducting quantum processing unit 300 includes superconductive materials and can be formed by patterning one or more superconductive (e.g., superconducting metal) layers or other materials on the surface of the substrate 320. In some implementations, each of the one or more superconductive layers include a superconducting metal, such as aluminum (Al), niobium (Nb), tantalum (Ta), titanium (Ti), vanadium (V), tungsten (W), zirconium (Zr), or another superconducting metal. In some implementations, each of the one or more superconductive layers may include a superconducting metal alloy, such as molybdenum-rhenium (Mo/Re), niobium-tin (Nb/Sn), or another superconducting metal alloy. In some implementations, each of the superconductive layers may include a superconducting compound material, including superconducting metal nitrides and superconducting metal oxides, such as titanium-nitride (TiN), niobium-nitride (NbN), zirconium-nitride (ZrN), hafnium-nitride (HfN), vanadium-nitride (VN), tantalum-nitride (TaN), molybdenum-nitride (MoN), yttrium barium copper oxide (Y—Ba—Cu—O), or another superconducting compound material. In some instances, the superconducting quantum circuit of the superconducting quantum processing unit 300 may include multilayer superconductor-insulator heterostructures.

In some implementations, the superconducting quantum circuit of the superconducting quantum processing unit 300 is fabricated on the top surface of the substrate 320 and patterned using a microfabrication process or in another manner. For example, the superconducting quantum circuit of the superconducting quantum processing unit 300 may be formed by performing at least some of the following fabrication steps: using chemical vapor deposition (CVD), physical vapor deposition (PVD), atomic layer deposition (ALD), spin-on coating, and/or other suitable techniques to deposit respective superconducting layers on the substrate 320; and performing one or more patterning processes (e.g., a lithography process, a dry/wet etching process, a soft/hard baking process, a cleaning process, etc.) to form openings in the respective superconducting layers.

The physical mechanisms underpinning the multi-qubit HOP gate using the example superconducting quantum processing unit 300 shown in FIG. 3 is now discussed. This includes both a micro-architecture based on transmon circuits with tunable-frequency coupler devices as well as system design considerations towards heat dissipation. Overall, embodiments include a five-qubit HOP gate via a pairwise dispersive interaction between a single stabilizer check qubit device and four local data qubit devices with equal coupling strength provided by the connections,

$${H}_{disp} = \frac{- ζ ( t )}{4} {\sum }_{k = 1}^{4} {σ}_{0} {σ}_{k} , \qquad ( 1 )$$

where ζ(t) is a time-dependent coupling strength (described in more detail soon), σ₀ is the Pauli-operator acting on the stabilizer check qubit device, (e.g., the second tunable-frequency qubit device 304), σₖ is the Pauli operator acting on the qubit defined by the k-th data qubit device (e.g., the first tunable-frequency qubit device 302A, 302B, 302C, 302D), and k=1, 2, 3, 4. In some instances, the Pauli operators may be Pauli-Z operators, or Pauli-X operators according to the locations of the first and second tunable=frequency qubit devices 302, 304) in the quantum error correction code layout. For example, when executing an quantum error correction code, in a X-type stabilizer check patch (e.g., 214A, 214B, 214C, 214D), the Pauli operators in the interaction Hamiltonian of Equation (1) may be Pauli-X operator (e.g., X₀, Xₖ); and in a Z-type stabilizer check patch (e.g., 212A, 212B, 212C, 212D in FIG. 2A), the Pauli operators in the interaction Hamiltonian of Equation (1) may be Pauli-Z operators (e.g., Z₀, Zₖ). In some instances, the second tunable-frequency qubit device 304 may be coupled to only two first tunable-frequency qubit device 302 to be used for executing a weight-three HOP gate, e.g., in X-type or Z-type stabilizer check patches 212C, 212D, 214C, 214D). In some instances, the second tunable-frequency qubit device 304 may be coupled to more than four first tunable-frequency qubit devices 302.

Allowing the five-qubit system evolve under this Hamiltonian with a constant coupling strength ζ₀ for a time τ=π/ζ₀ corresponds to applying a total unitary U=exp{iπ/4ΣₖZ₀Zₖ} which is equivalent to the quantum logic circuit 270 with four CZ gates shown in FIG. 2B up to single-qubit phase gates applied to the qubits defined by the data qubit devices (e.g., \sqrt{Z} rotations on each). Within the Z-check protocol shown in FIG. 2B, the 5-qubit system is biased with no interactions (ζ(0)=0), and in this configuration, the qubit defined by the stabilizer check qubit device is prepared along the X-axis via a Hadamard (H) gate (e.g., the Hadamard gate 252 in FIG. 2B). After turning on the interaction and waiting an amount r, the interaction is turned off ζ(t≥τ)=0. A final Hadamard gate maps the state of the stabilizer check qubit device as [symbol] (Z₀ [symbol] =−1 for an even number of excited data qubit devices, and [symbol] Z₀ [symbol] =+1 for an odd number of excited data qubit devices. Thus, the five-qubit HOP gate enable a single-operation stabilizer check on the four data qubit devices. For the typical gate-model configurations considered here, estimates of ζ/2 π=5 MHz corresponds to a HOP gate time of τ=100 ns. In some implementations, measuring X-stabilizers instead has H gates applied to the qubits defined by the data qubit devices but otherwise follows the same protocol.

In some implementations, the Hamiltonian in Equation (1) can be realized by coupling the stabilizer check qubit device (e.g., the second tunable-frequency qubit device 304 in FIG. 3) to the data qubit devices (e.g., the first tunable-frequency qubit device 302 in FIG. 3) using the tunable-frequency coupler devices (e.g., the tunable-frequency coupler device 306a in FIG. 3). In some implementations, the electrodes 312 of the tunable-frequency coupler devices 306 are asymmetric, e.g., having different shapes of footprints, different areas of the footprints, and/or different distances to the electrodes of the respective first and second tunable-frequency qubit devices 302, 304. For this type of coupler device, a zero-coupling condition is achieved by placing the transition frequency of the tunable-frequency coupler device 306 above the transition frequencies of the first and second tunable-frequency qubit devices 302, 304. The qubit-qubit coupling between a first tunable-frequency qubit device 302 and the second tunable-frequency qubit device 304 can be varied and tuned from ζ=0 to the target coupling strength ζ₀ by tuning the flux bias applied to the superconducting circuit loop 308 of a respective tunable-frequency coupler device 306. In some implementations, multiple couplings between each of the first tunable-frequency qubit devices 302 and the second tunable-frequency qubit device 304 are achieved simultaneously, for example, by applying flux biases to each of the superconducting circuit loops 308 of the first and second tunable-frequency qubit devices 302, 304 and the respective tunable-frequency coupler devices 306. In certain instances, the electrodes 312 of the tunable-frequency coupler devices 306 are symmetric, e.g., having identical shapes or footprints, same areas of the footprints, and/or same distances to the electrodes of the respective first and second tunable-frequency qubit devices 302, 304.

In some implementations, the HOP-based surface code is operated at a static flux bias that causes the coupling strength ζ(t)=ζ₀, Removing active controls for entangling gates would address a major challenge towards managing the thermal heat load of large-scale superconducting processors—approximately halving the dissipation at cryogenic temperatures. First, for systems running HOP gates exclusively for entanglement, all DC current bias can be delivered over twisted pair (TwP) superconducting wire (for instance, niobium-titanium alloys) instead of coaxial signal delivery, which is otherwise standard for high-bandwidth two-qubit gate signals. This rewiring, alone, would amount to a hundredfold reduction in passive heat load at the coldest stages of the dilution refrigerator for two-qubit signals, eliminating approximately 40% of the total estimated thermal budget. Moreover, another 10% of total thermal budget would be saved by eliminating the active heat load from fast two-qubit gate pulses. Maintaining an equal thermal footprint while doubling the number of physical qubits could prove to be a leading motivation for HOP gates.

The example superconducting quantum processing unit 300 with five tunable-frequency qubit devices 302, 304 and four tunable-frequency coupler devices 306 can be described by the following Hamiltonian with a three-level approximation for each anharmonic mode:

$${{H = {\sum }_{j = 0}^{4} {ω}_{j} ( {Φ}_{j} ) \vert 1 〉}_{j} 〈 1 \vert + ( 2 {ω}_{j} ( {Φ}_{j} ) - {η}_{j} ( {Φ}_{j} ) ) \vert 2 〉}_{j} 〈 2 \vert + \qquad ( 2 )$$

$${{{\\ \sum }_{k = 1}^{4} {ω}_{{c}_{k}} ( {Φ}_{k} ) \vert 1 〉}_{{c}_{k}} 〈 1 \vert + [ 2 {ω}_{{c}_{k}} ( {Φ}_{k} ) - {η}_{{c}_{k}} ( {Φ}_{k} ) ] \vert 2 〉}_{{c}_{k}} 〈 2 \vert +$$

$${\\ \sum }_{m = 1}^{4} [ {g}_{0 m} {X}_{0} {X}_{m} + {g}_{0 {c}_{m}} {X}_{0} {X}_{{c}_{m}} + {g}_{{mc}_{m}} {X}_{m} {X}_{{c}_{m}} ] ,$$

where ωⱼ and ηⱼ are the jth qubit frequency and anharmonicity of the first tunable-frequency qubit devices 302; ω_{ck} and η_{ck} are frequency and anharmonicity of the kth tunable-frequency coupler device 306, g₀ₘ, (m ∈ [1,4]) are the direct couplings between the second tunable-frequency qubit device 304 and each of the first-tunable qubit devices 302, g_{0c}_{ₘ} (m ∈ [1,4]) are the couplings between the second tunable-frequency qubit device 304 and the tunable-frequency coupler device 306, and g_{mc}_{ₘ}(m ∈ [1,4]) are the couplings between the first tunable-frequency qubit device 302 and each of the tunable-frequency coupler devices 306. Here Xⱼ=σ_{-,j}+σ_{+,j}, where σ_{-,j}=|0 [symbol] ⱼ [symbol] 1|+√2|1 [symbol] ⱼ [symbol] 2| is the lowering operator for the jth first tunable-frequency qubit device 302 or the tunable-frequency coupler device 306. In some implementations, the first tunable-frequency qubit devices 302 and the tunable-frequency coupler devices 306 are flux tunable transmon qubit devices and their transition frequencies as a function of the flux bias can be approximated by

$${ω}_{m} ( {Φ}_{m} ) = \sqrt{8 {E}_{Jeff , m} {E}_{C , m}} - {E}_{C , m} ( 1 + {ξ}_{m} / 4 + 21 {ξ}_{m}^{2} / 128 ) , \qquad ( 3 )$$

$${η}_{m} ( {Φ}_{m} ) = {E}_{C , m} ( 1 + 9 {ξ}_{m} / 16 + 81 {ξ}_{m}^{2} / 128 ) , \qquad ( 4 )$$

$${E}_{Jeff , m} = \frac{{E}_{J , m}}{1 + {r}_{m}} \sqrt{1 + {r}_{m}^{2} + 2 {r}_{m} cos ( 2 π {Φ}_{m} / {Φ}_{0} )} , \qquad ( 5 )$$

where m ∈ {[1,4], [c₁, c₄]}, ξₘ=\sqrt{2E_{C,m}/E_{Jeff,m}} and rₘ=E_{J1,m}/E_{J2,m} is the ratio of the junction energies, E_{J1,m}E_{J2,m} of the SQUID, E_{C,m} is the charging energy, and E_{J,m}=E_{J1,m}+E_{J2,m} is the total junction energy; Φₘ and Φ₀ are the external flux bias and flux quantum, respectively. Note that the qubit-coupler couplings g_{0c}_{ₘ} and g_{mc}_{ₘ} depend on the external flux biases Φₘ. Explicit dependence of the these couplings are used when computing the nearest neighbor (Z₀Zₖ) and next-nearest neighbor (Z_{j≠0}Zₖ) couplings. The designed operating point assumes flux-biasing to adjust all first and second tunable-frequency qubit devices 302, 304 to their maximum frequencies and all tunable-frequency coupler devices 306 to their minimum frequencies (e.g., Φₖ=0.5 Φ₀) in order to maximize the dispersive qubit-qubit couplings between each of the first tunable-frequency qubit devices 302 and the second tunable-frequency qubit device 304, while keeping the Z_{j≠0}Zₖ coupling minimum. In some implementations, small bias adjustments are anticipated and required to account for fabrication tolerances.

In some implementations, the coupling strengths can be estimated numerically by exact diagonalization of the Hamiltonian including three energy levels for each of the first and second tunable-frequency qubit devices 302, 304, and the tunable-frequency coupler devices 306 (3⁹ dimensions). The dispersive coupling strengths ζⱼₖ for each interaction can be identified as the frequency difference,

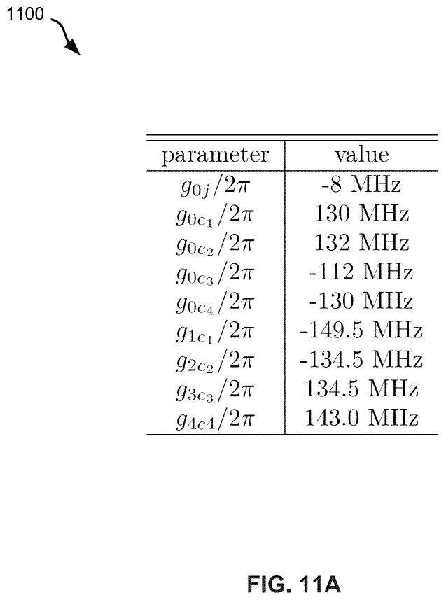

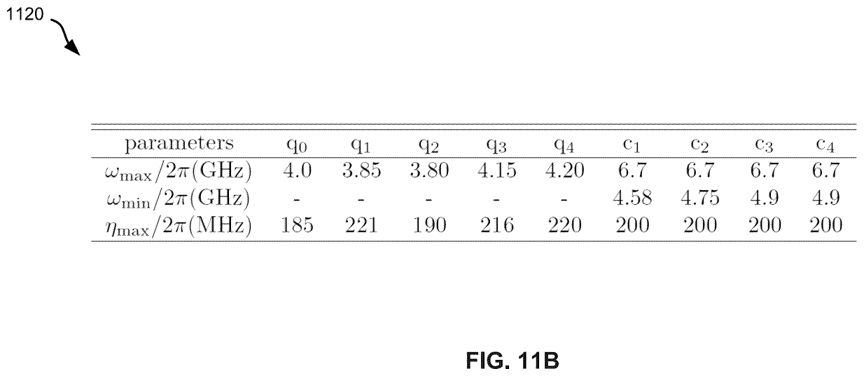

ζⱼₖ= [symbol] + [symbol] − [symbol] − [symbol] (6)

where [symbol] is the eigenfrequency associated with n (m) excitations in the j-th (k-th) mode and −ζⱼₖ/4 is the weight of the ZⱼZₖ term in the interaction Hamiltonian as in Equation (1). For realistic parameters for a tunable-frequency coupler device and tunable-frequency qubit devices given in FIGS. 11A and 11B, the following may be used: ζ₀ₖ/2 π=5.0 MHz and ζⱼₖ/2 π=2-24 kHz for j≠0. These parameters can be used for the construction of the error model and subsequent fault-tolerant analysis described later in this Disclosure.

In some implementations, the nearest neighbor and next-nearest neighbor ZZ coupling strength are calculated by diagonalizing the full five-qubit Hamiltonian given by Equation (2). The nearest neighbor ZZ coupling strength between the second tunable-frequency qubit device (e.g., stabilizer check qubit device) and each of the first tunable-frequency qubit devices (e.g., data qubit devices) are

ζ₀₁= [symbol] + [symbol] − [symbol] − [symbol] (7)

ζ₀₂= [symbol] + [symbol] − [symbol] − [symbol] (8)

ζ₀₃= [symbol] + [symbol] − [symbol] − [symbol] (9)

ζ₀₄= [symbol] + [symbol] − [symbol] − [symbol] (10)

and the next-nearest neighbor couplings between data qubits are given by

ζ₁₂= [symbol] + [symbol] − [symbol] − [symbol] (11)

ζ₁₃= [symbol] + [symbol] − [symbol] − [symbol] (12)

ζ₁₄= [symbol] + [symbol] − [symbol] − [symbol] (13)

ζ₂₃= [symbol] + [symbol] − [symbol] − [symbol] (14)

ζ₂₄= [symbol] + [symbol] − [symbol] − [symbol] (15)

ζ₃₄= [symbol] + [symbol] − [symbol] − [symbol] (16)

This Disclosure now sets out to provide a description of the noise model associated with the multi-qubit HOP gate that is compatible with fault-tolerant analysis. A noisy quantum process can be described as a superoperator ε(ρ) that takes an initial density matrix ρ to a final density matrix. A quantum circuit can be as the composition of the ideal unitary channel U and an error channel Λ:

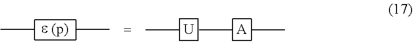

with time proceeding from left to right. Formally, that basis change is conducted via:

$$ε ( ρ ) = Λ ∘ U ( ρ ) = {\sum }_{i , j = 0}^{{d}^{2} - 1} {χ}_{i j}^{Λ} {𝒫}_{i} U ρ {U}^{†} {𝒫}_{j}^{†} , \qquad ( 18 )$$

where χ^{Λ} is an error process matrix; and { [symbol] ₖ} are elements of the multi-qubit Pauli operators, [symbol] ₖ ∈ {I, X, Y, Z}^{⊗n}. This allows us to look at errors in an interaction picture. For instance, the ideal unitary channel: ε(ρ)=UρU† has only one non-zero element χ₀₀^{Λ}=1 with [symbol] ₀₀=I^{⊗n}.

To study the effect of noise in the context of surface codes using multi-qubit HOP gates, where stabilizer-type simulations are desired, one can include noisy single-qubit Pauli gates to perform Pauli-twirling of an error channel Λ, with the twirled error channel denoted as \tilde{Λ}. In the twirling approximation, the twirled error process matrix χ^{\tilde{Λ}} is diagonal with eigenvalues pₖ each of which is a real-valued number. The weight of pₖ is the probability that the \tilde{Λ} channel applies the [symbol] ₖ rotation, instead of the desired I^{⊗n} element. Following the convention in Equation (18), these probabilistic Pauli gates occur after the perfect unitary.

To estimate χ^{Λ}, one can solve the Lindblad master equation (ME) governing the HOP gate under the types of Markovian decoherence that are the main noise in superconducting qubits, namely energy loss T₁ processes and pure dephasing T_{ϕ} processes. These act concurrently with interaction Hamiltonian of the gate defined in Equation (1) to evolve the density matrix as

$$\begin{matrix}\frac{d ρ}{d t} = - i [ H , ρ ] + {\sum }_{j} [ {L}_{j} ρ {L}_{j}^{†} - \frac{1}{2} {L}_{j} {L}_{j}^{†} ρ - \frac{1}{2} ρ {L}_{j} {L}_{j}^{†} ] \\ ≡ ℒ ( t ) ρ ( t )\end{matrix} \qquad ( 19 )$$

where Lⱼ are Lindblad jump operators, and [symbol] is an infinitesimal generator of the evolution sometimes called the Liouvillian superoperator.

While this Disclosure will soon allow for decoherence acting each of the five qubits in the multi-qubit HOP gate, for the time being, this Section considers the effect of noise on the stabilizer check qubit device only, which can help develop an intuition for the subsequent full analysis. In this case, the Lindblad jump operators are

Lⱼ ∈ {\sqrt{Γ₁}σ−⊗I^{⊗4}, \sqrt{Γ_{ϕ}}Z⊗I^{⊗4}}, (20)

where Γ₁=1/T₁ and Γ₉₉ =1/T₉₉ for the stabilizer check qubit device, and I^{237 4} acts on the data qubit register. This single-qubit noise generates multi-qubit back-action on the data qubits. To see this, it is helpful to consider Equation (19) in the rotating frame of the interaction Hamiltonian defined in Equation (1), as

ρ(t)≡e^{iHt}ρ(t)e^{-iHt} (21)

and the jump operators similarly get transformed

$${\tilde{σ}}_{-} ( t ) = {e}^{iHt} {σ}_{-} {e}^{- iHt} = exp - i \frac{ζ t}{4} {\sum }_{k} {Z}_{k} {σ}_{-} , \qquad ( 22 )$$

$$\tilde{Z} ( t ) = {e}^{iHt} Z {e}^{- iHt} = Z$$

Energy decay of the stabilizer check qubit device generates a phase kick onto the qubits defined by the data qubit devices that is time-dependent, amplifying the effect of that error in the multi-qubit HOP gate. On the other hand, a dephasing event commutes through the Hamiltonian during the actuation of the multi-qubit HOP gate, and therefore, remains a single-qubit error. Similarly, when one includes single-qubit decoherence on the qubits defined by the data qubit devices, energy relaxation from any of the data qubit devices gives a phase kick to the stabilizer check qubit.

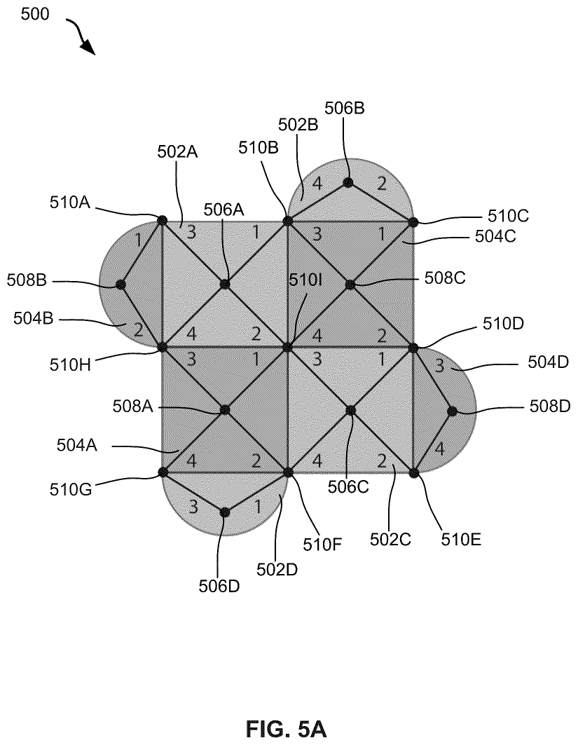

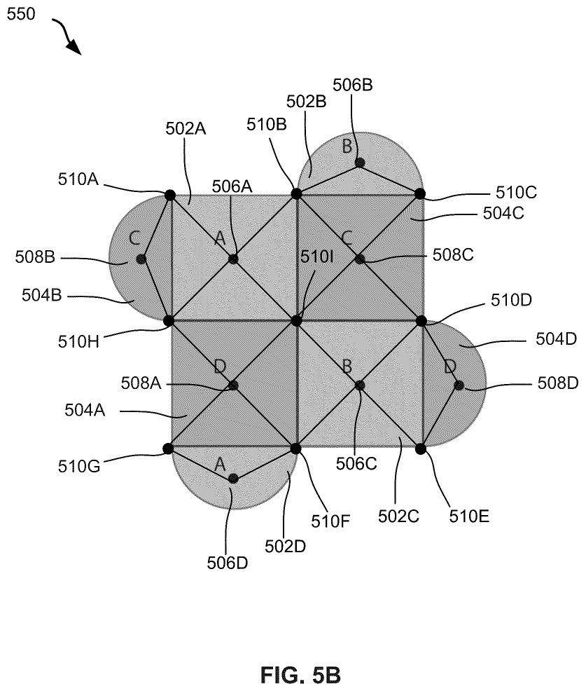

The 5-qubit interactions (e.g., as represented by the stabilizer check patches 212A, 212B, 214A, 214B, 502A, 504A, 504C, 502C in FIGS. 2A and 5A-5B) and 3-qubit interactions (e.g., as represented by the stabilizer check patches 212C, 212D, 214C, 214D, 502B, 504B, 502D, 504D in FIGS. 2A and 5A-5B) are represented in our circuit-level error model via perfect entangling gates followed by a correlated 5-qubit or 3-qubit Pauli channel:

$${ε}_{5 / 3} ( ρ ) = {\sum }_{A ∈ {5 / 3}_{}} {p}_{A} A ρ {A}^{†} , \qquad ( 23 )$$

where p_{A} is the probability that Pauli A ∈ [symbol] _{5/3} occurs. Recall that the characteristic parameter p of the channel describes the strength of the noise in the system, and that p>p_{A} for any Pauli A.

In some implementations, Stim (a stabilizer circuit simulator) is used. Examples of the simulator are described in the publication entitled “Stim: A fast stabilizer circuit simulator” by Craig Gidney (Quantum 5, 497, 2021). Stim allows the use of a channel that applies an arbitrary multi-qubit Pauli operator with probability p, and otherwise applies the identity, with probability 1−p:

ε_{A,p}(ρ)−(1−p)ρ+pAρA†, A ∈ [symbol] ₙ (24)

Such channels may be referred to as single-outcome Pauli channels. One way of approximating ε_{5/3} is to replace it with a channel ε′_{5/3} which sequentially applies a separate single-outcome Pauli channel ε_{A,p}_{ₐ} for each non-trivial Pauli operator A ∈ [symbol] _{5/3} with its corresponding probability p A . Our desired channel ε_{5/3} applies Pauli A with probability P A , and by comparison, our approximate channel ε′_{5/3} will apply Pauli A with probability

$${p}_{A}^{′} = {p}_{A} + {C}_{A , {p}^{2}}^{′} + {C}_{A , {p}^{3}}^{′} + … + {C}_{A , {p}^{{4}^{5 / 3}}}^{′} , \qquad ( 25 )$$

where C′_{A,p}^{k} is the sum of all probabilities that exactly k of the single-outcome channels of ε′_{5/3} apply non-trivial Paulis whose product gives the Pauli A. Because p>p_{A}, the following is shown:

p′_{A}=p_{A}+O(p²) (26)

This indicates that ε′_{5/3} approximates ε_{5/3} to first order in p, and could be a reasonable approximation for small values of p.

This approximation may be improved, in some cases, to order O(p²) with a reasonable computational overhead by computing C′_{A,p}_{²} for each A ∈ [symbol] _{5/3} and shifting the probabilities for each of the single-outcome Pauli channels to p_{A}−C′_{A,p}_{²}. The channel built with this procedure is referred to as ε″_{5/3}.

Lemma: The channel ε″_{5/3} applies pauli A with probability p_{A}+O(p³).

Proof: Under the shift p_{A}→p_{A}−C′_{A,p}_{²}, the probability of applying A is

$${p}_{A}^{″} = {p}_{A} - {C}_{A , {p}^{2}}^{′} + {C}_{A , {p}^{2}}^{″} + {C}_{A , {p}^{3}}^{″} + … + {C}_{A , {p}^{{4}^{5 / 3}}}^{″} , \qquad ( 27 )$$

where the terms C″_{A,p}_{^{k}} are defined appropriately with the shifted probabilities. Examining C″_{A,p}_{²}, one can consider:

$${C}_{A , {p}^{2}}^{″} = {\sum }_{B , C s . t . BC ∼ A} ( {p}_{B} - {C}_{B , {p}^{2}}^{′} ) ( {p}_{C} - {C}_{C , {p}^{2}}^{′} ) = {\sum }_{B , C s . t . BC ∼ A} {p}_{B} {p}_{C} + O ( {p}^{3} ) = {C}_{A , {p}^{2}}^{′} + O ( {p}^{3} ) , \qquad ( 28 )$$

so that

p″_{A}=p_{A}−C′_{A,p}_{²}+C′_{A,p}_{²}+O(p³)=p_{A}+O(p³) (29)

as desired.

In some implementations, the channel ε″_{5/3} instead of ε_{5/3} is implemented in Stim.

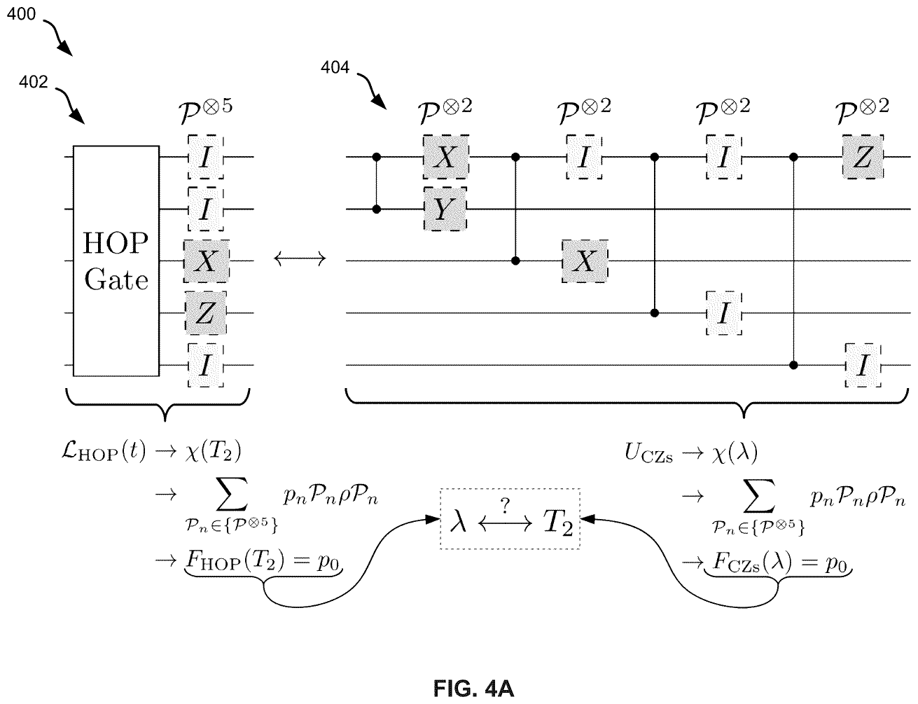

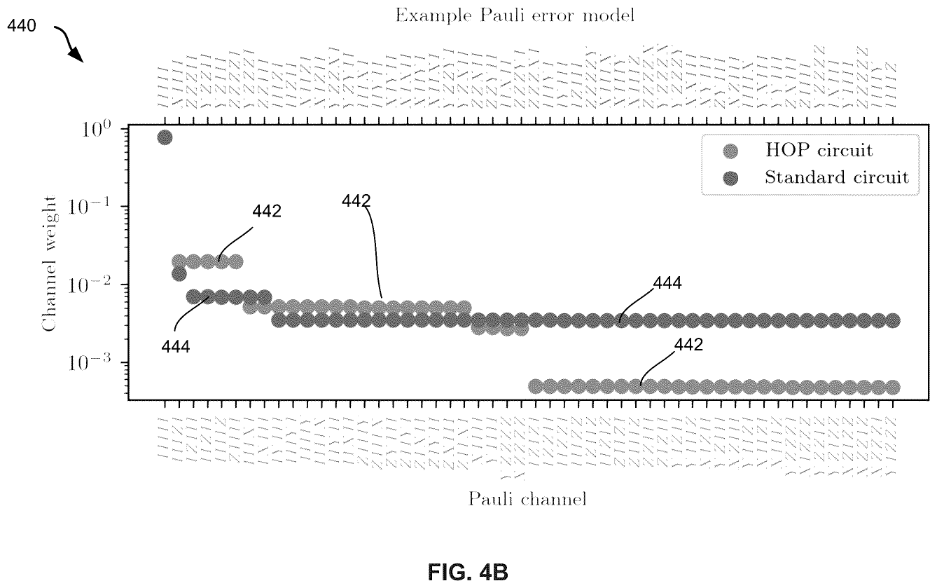

FIG. 4A is a schematic diagram 400 showing aspects of example quantum logic circuits and their respective Pauli error models. Comparing the five-qubit Pauli error model for the mult-qubit HOP gate 402 to a corresponding two-qubit depolarizing error model for the standard circuit 404, illustrated by an unwanted [symbol] ∈ [symbol] ^{⊗5} error for the multi-qubit HOP gate 402 and unwanted [symbol] ∈ [symbol] ^{⊗2} errors after every two-qubit gate for the standard circuit 404. The Louiviallian superoperator for a full HOP gate [symbol] _{HOP}(t) is used to get the error process matrix χ parameterized by coherence times T₂, from which an embodiment may get an approximated error model made up of five-qubit Paulis [symbol] ={I, X, Y, Z}^{⊗5}. The equivalent operation made up of four CZ gates in the standard circuit 404 each undergoing two-qubit depolarizing noise is used to produce a superoperator process unitary U_{CZS}, from which we get the process matrix for an effective five-qubit Pauli channel parameterized by a two-qubit depolarizing rate λ. We equate the process fidelities F_{HOP}(T₂)=F_{CZs}(λ) to determine an equivalence between λ and T₂.

FIG. 4B is a plot 440 showing channel weight as a function of Pauli channel for the multi-qubit HOP gate 402 and the standard circuit 404 shown in FIG. 4A. Data points 442 represents the channel weight as a function of Pauli channels for the multi-qubit HOP gate 402 in FIG. 4A; and data points 444 represents the channel weight as a function of Pauli channels for the standard circuit 404 in FIG. 4A. Resulting error models from the analysis using Γ₂=1/T₂=0.05 and a corresponding λ≈0.066, for channel weights>3×10⁻⁴ (arbitrary cutoff chosen for fitting to plot), comparing the effective error channels for both equivalent circuits. Note the process fidelities given by IIIII are equal.

One can turn to numerics to solve the ME with equal decoherence rates across all qubits. Specifically, a quantum system simulater, such as Quantum Toolbox in Python (“QuTiP”), can be used to find the propagator Vₜ, which is a superoperator describing the full noisy channel, as Vₜ(ρ(0))=ρ(t), by numerically integrating the Liouvillian:

Vₜ= [symbol] exp∫₀^{t}ds [symbol] (s) (30)

where [symbol] is the time-ordering operator. The time τ for the evolution is chosen such that the interaction Hamiltonian achieves the correct entangling phase (τ=π/ζ₀). To estimate the error process matrix χ^{Λ}, one can perform tomography on the composite channel: Vₜ∘U† with U the target multi-qubit phase gate, U=expi(π/4)ΣₖZ₀Zₖ. Pauli twirling removes the off-diagonal terms of χ^{Λ}. That yields χ^{\tilde{Λ}}, from which the weights pₖ of the corresponding Pauli channels [symbol] ₖ are obtained. Succinctly, this procedure allows for a low-level description of the example systems from Equations (1) and (30) to establish a description of the error model of the form of

$${\tilde{Λ}}_{HOP} ( ρ ) = {\sum }_{i = 0}^{1023} {w}_{i} {i}_{} ρ {i}_{} , {i}_{} ∈ {\{ I , X , Y , Z \}}^{⊗ 5} , \qquad ( 31 )$$

which may be analyzed with a parameterized noise model: e.g., take a physical error rate p for our fault-tolerance calculations given by the HOP gate time and the single-qubit decoherence rate as p=τΓ₂, with Γ₂=Γ₁/2+Γ₉₉ . To reduce the simulation overhead, embodiments may make the further assumption that Γ₉₉=Γ₁/2(T₁=T₂), which is typical of superconducting qubit devices, and ignore leakage states. With this approach, a more complete error model may be produced, as illustrated in FIG. 4B that includes energy loss and dephasing on all five qubits. Additionally, this framework may be used to investigate undesired effects including the coherent ZZ cross-talk anticipated for next-nearest neighbors by adding these terms to the ME. Exploring the effects using parameters guided by simulated results, it is to be appreciated that no discernible impact on the resulting error model and subsequent logical error threshold calculations were found. Thus, for simplicity, the following section reports only results from the decoherence model.

One interesting point is to understand how the HOP gate may perform in the context of error correction. Towards that end a comparison point is discussed here based on a simplified quantum channel construction using the logically equivalent quantum logic circuit 404 with four CZ gates as shown in FIG. 4A, which may be referred to as the standard construction or the standard circuit. For the standard construction, the following two-qubit depolarizing noise applied after each CZ gate is assumed:

$${Δ}_{λ} ( ρ ) = {\sum }_{i = 0}^{15} {v}_{i} {K}_{i} ρ {K}_{i} , \qquad ( 32 )$$

where the operators Kᵢ are two-qubit Pauli operators [symbol] ᵢ ∈ [symbol] ^{⊗2} with the corresponding weights

$${v}_{0} = 1 - \frac{15 λ}{16} , \qquad ( 33 )$$

$${v}_{k \neq 0} = \frac{λ}{16} .$$

Some of these depolarizing errors are amplified in the standard circuit, resulting in a non-trivial five-qubit error process matrix \tilde{∧}_{CZ} with an equivalent form as Equation (31).

Recognizing that the overall process fidelity is \tilde{∧}_{HOP}⁾⁾=F_{HOP}(T₂) and \tilde{∧}_{CZ}⁰⁰=F_{CZ}(λ), one can set F_{HOP}(p)=F_{CZ}(λ) to determine what two-qubit depolarizing rate A is comparable to p. Using this procedure for determining equal fidelity (setting a consistent Physical Error Rate) produces the error models shown in FIG. 4B, where its noted that the channel weights for the Pauli I^{⊗5} are the same. The differences in the distribution of errors across the Pauli strings illustrates the non-triviality of the relationship between these two logically equivalent processes. It is observed that the most prominent Pauli channels are different between the two methods. Moreover, nearly half of Pauli channels for the multi-qubit HOP gate 402 are an order of magnitude smaller than for the standard circuit 404. In some implementations, the systems and techniques disclosed in this application can provide advantages. For example, the gate error of the mult-qubit HOP gate 402 can be simpler to characterize and operate in practice compared to the standard circuit 404.

In some implementations, efficacy of performing fault-tolerant error correction via the rotated surface code using a parity-check syndrome measurement circuit based on multi-qubit HOP gates is examined. In particular, logical failure rates and the fault-tolerant threshold achievable using the parity-check syndrome measurement circuit based on multi-qubit HOP gates (e.g., the multi-qubit HOP gate 254 in FIG. 2B) are compared against a parity-check syndrome measurement circuit based on a standard circuit that includes two-qubit entangling gates (e.g., the standard circuit 404 in FIG. 4).

In an example surface code architecture, a single fault-tolerant error correction cycle may be made up of d consecutive rounds of syndrome measurements, where d is the distance of the stabilizer check patch encoding a logical qubit. Each round of syndrome measurements consists of a single measurement of each of the X and Z-type stabilizer check patches of the surface code. Repeated rounds of syndrome measurements aid in offsetting the effects of measurement errors which corrupt the measured syndrome.

Individual stabilizer generators are measured non-destructively by coupling the relevant data qubit devices to a single stabilizer check qubit device which is then measured to infer the outcome. In some instances, this can be achieved using CX or CZ gates applied to the qubits defined by data qubit devices and the stabilizer check qubit devices (e.g., the standard circuit 404 in FIG. 4A). In this case, this surface code architecture allows for measurements on all the stabilizer check qubit devices in a single round to be carried out simultaneously in parallel when using two-qubit entangling gates (as shown FIG. 5A). By mandating a specific schedule for the order in which the two-qubit gates are executed, one can avoid reducing the effective distance of the surface code by spreading X or Z errors along their respective logical directions.

FIG. 5A is a schematic diagram showing a schedule of surface code operations of a standard syndrome measurement circuit 500 in the example quantum error correction code layout 200 shown in FIG. 2A, according to an example embodiment. As shown in FIG. 5A, patches 502A, 502B, 502C, 502D represent Z-type stabilizer check patches; patches 504A, 504B, 504C, 504D represent X-type stabilizer check patches; black circles 510A, 510B, 510C, 510D, 510E, 510F, 510G, 510H, 5101 on vertices represent data qubit devices; black circles 506A, 506B, 506C, 506D, 508A, 508B, 508C, 508D on faces of stabilizer check patches represent stabilizer check qubit devices; and diagonal lines between two black circles denote two-qubit gates (e.g., CX gates for X-checks or CZ gate for Z-checks) applied on qubits defined by respective pairs of stabilizer qubit devices and data qubit devices.

As shown in FIG. 5A, at least a subset of the two-qubit gates in distinct stabilizer check patches is performed simultaneously in the order indicated (e.g., 1, 2, 3, 4 in FIG. 5A), which allows for measurements on the stabilizer check qubit devices f a distance 3 rotated surface code to be carried out in parallel while avoiding certain fault mechanisms that could reduce the effective distance of the surface code. In particular, in a single round of stabilizer checks, an optimized scheduling of the surface code operations, two-qubit gates applied to a pair of qubits defined by the stabilizer check qubit 506A and the data qubit device 510B, a pair of qubits defined by the stabilizer check qubit 506C and the data qubit device 510D, a pair of qubits defined by the stabilizer check qubit 508A and the data qubit device 5101, a pair of qubits defined by the stabilizer check qubit 508C and the data qubit device 510C, a pair of qubits defined by the stabilizer check qubit 506D and the data qubit device 510F, and a pair of qubits defined by the stabilizer check qubit 508B and the data qubit device 510A can be performed in parallel during a first time period; two-qubit gates applied to a pair of qubits defined by the stabilizer check qubit 506A and the data qubit device 5101, a pair of qubits defined by the stabilizer check qubit 506C and the data qubit device 510E, a pair of qubits defined by the stabilizer check qubit 508A and the data qubit device 510F, a pair of qubits defined by the stabilizer check qubit 508C and the data qubit device 510D, a pair of qubits defined by the stabilizer check qubit 506B and the data qubit device 510C, and a pair of qubits defined by the stabilizer check qubit 508B and the data qubit device 510H can be performed in parallel during a second time period; two-qubit gates applied to a pair of qubits defined by the stabilizer check qubit 506A and the data qubit device 510A, a pair of qubits defined by the stabilizer check qubit 506C and the data qubit device 5101, a pair of qubits defined by the stabilizer check qubit 508A and the data qubit device 510H, a pair of qubits defined by the stabilizer check qubit 508C and the data qubit device 510B, a pair of qubits defined by the stabilizer check qubit 506D and the data qubit device 510G, and a pair of qubits defined by the stabilizer check qubit 508D and the data qubit device 510D can be performed in parallel during a third time period; and two-qubit gates applied to a pair of qubits defined by the stabilizer check qubit 506A and the data qubit device 510H, a pair of qubits defined by the stabilizer check qubit 506C and the data qubit device 510F, a pair of qubits defined by the stabilizer check qubit 508A and the data qubit device 510G, a pair of qubits defined by the stabilizer check qubit 508C and the data qubit device 5101, a pair of qubits defined by the stabilizer check qubit 506B and the data qubit device 510B, and a pair of qubits defined by the stabilizer check qubit 508D and the data qubit device 510E can be performed in parallel during a fourth time period.

An alternative syndrome measurement circuit for the HOP surface code (e.g., an HOP syndrome measurement circuit) is now described. One potential benefit of using the multi-qubit HOP gates to perform stabilizer checks instead of two-qubit gates is that a single-operation stabilizer check can effectively be performed faster. However, when using the multi-qubit HOP gates, one loses the ability to perform stabilizer checks in parallel as was possible with the standard circuit. Extra time before and after each multi-qubit HOP gate may also be incurred in order to include the twirling steps that justify our error model.

FIG. 5B is a schematic diagram showing a schedule of surface code operations of a HOP syndrome measurement circuit 550 in the example quantum error correction code layout 200 shown in FIG. 2A. As shown in FIG. 5B, patches 502A, 502B, 502C, 502D represent Z-type stabilizer check patches; patches 504A, 504B, 504C, 504D represent X-type stabilizer check patches; black circles 510A, 510B, 510C, 510D, 510E, 510F, 510G, 510H, 5101 on vertices represent data qubit devices; black circles 506A, 506B, 506C, 506D, 508A, 508B, 508C, 508D on faces of stabilizer check patches represent stabilizer check qubit devices; and diagonal lines between two black circles denote couplings between stabilizer check qubit devices and the data qubit devices.

As shown in FIG. SB, a group of stabilizer checks using a multi-qubit HOP gate within a stabilizer check patch can be performed separately. In particular, a group of stabilizer checks in the Z-type stabilizer check patches 502A, 502D are performed in parallel during a first time period; a group of stabilizer checks in the Z-type stabilizer check patches 502C, 502B are performed in parallel during a second time period; a group of stabilizer checks in the X-type stabilizer check patches 504B, 504C are performed in parallel during a third time period; and a group of stabilizer checks in the X-type stabilizer check patches 504A, 504D are performed in parallel during a fourth time period. In some implementations, each group of stabilizer checks is followed by the correlated multi-qubit noise channels on the qubits that participated in the respective group of stabilizer checks.

As shown in FIG. SB, A plaquettes include the Z-type stabilizer check patches 502A, 502D; B plaquettes include the Z-type stabilizer check patches 502B, 502C; C plaquettes include the X-type stabilizer check patches 504B, 504C; and D plaquettes include the X-type stabilizer check patches 504A, 504D.

The circuit-level error models that one can use to simulate error correction using either circuit are characterized by the single parameter p described in Sec. 3. Any single qubit gate location (Hadamard, Pauli twirl or idle/identity) is followed by a single qubit depolarizing channel of strength p₁=p/10. Preparation of stabilizer check qubit devices and measurement locations fail with probability pₚₘ=p/2, where a preparation failure causes the preparation of the state orthogonal to the one intended, and a measurement failure flips the measurement outcome. For the standard circuit, the failure rate of the two-qubit gates, p₂, is set by demanding that the process fidelity of performing a full single stabilizer check using two-qubit gates is equal to the process fidelity of performing the stabilizer check with the 5-qubit HOP gate. This allows us to characterize the effects of high-weight correlated errors from the HOP gates relative to the lower weight errors caused by failures of two-qubit gates.

In some implementations, simultaneous stabilizer check of the same type {A,B} and {C,D} are performed, since the Hamiltonian for these HOP gates are mutually commuting. Moreover, an error in one qubit during the HOP gate causes, at worst, a phase flip on one of the gate targets. However, phase errors commute with the HOP Hamiltonian, meaning errors would remain local during simultaneous HOP gates, even though data qubits undergo multiple HOP gates in parallel.

FIG. 6 is a flow chart showing aspects of an example surface code syndrome measurement process 600. In some implementations, the example process 600 represents a single round of operations in a surface code syndrome measurement circuit (e.g., the HOP syndrome measurement circuit 550 in FIG. 5B). The example process 600 includes a series of operations actuated by one or more classical computing systems of a control system (e.g., the control system 105A, 105B in FIG. 1) and executed on a superconducting quantum processing unit (e.g., the quantum processing unit 103A, 103B, 300 in FIGS. 1 and 3). The example process 800 may include additional or different operations, including operations performed by additional or different quantum circuit devices, and the operations may be performed in the order shown or in another order.

In particular, the example process 600 includes operations 602, 606, 610, 614, 618, each of which includes twirling the data qubit devices in respective stabilizer check patches by applying random single-qubit Pauli operators to the data qubits defined by the data qubit devices in order to justify the twirling approximation, and Hadamard gates on the data qubits defined by the data qubit devices in the respective stabilizer check patches to execute X-type stabilizer checks, with the assumption that the Hadamard gates can be compiled into the Twirling steps if desired. The example process 600 further includes operations 604, 608, 612, 616, each of which includes sub-operations including preparing respective stabilizer check qubit devices (e.g., by performing the Hadamard gate 252 in FIG. 2B); tuning couplings of the stabilizer check qubit devices with respective data qubit devices in the same stabilizer check patch via the appropriate multi-qubit HOP gates; evolving the stabilizer check qubiht device and the respective data qubit devices in the same stabilizer check patches under an interaction Hamiltonian as defined in Equation (1); and performing measurements on the respective stabilizer check qubit devices (e.g., performing the measurement 258 as shown in FIG. 2B).

In some implementations, a stabilizer surface simulator (e.g., Stim) is used to generate Monte Carlo samples of fault patterns and their associated syndrome patterns in our syndrome measurement circuits assuming d noisy rounds of syndrome measurement followed by one perfect round to project back to the codespace. For each sample, an embodiment may feed the results to a minimum-weight perfect matching (MWPM) decoder implemented in Python using PyMatching and record whether or not the decoder's correction causes a logical failure by flipping a hypothetical measurement outcome of the logical Z or X operators of the code. In some implementations, the multi-qubit correlated channels are approximated in our simulations by using appropriately chosen single outcome Pauli channels. Under this approximation, the probabilities of any correlated Pauli error occurring after a multi-qubit interaction gate differ from the probabilities intended by the true error model deviate only by corrections that are O (p³), which should be irrelevant in the low p regime.

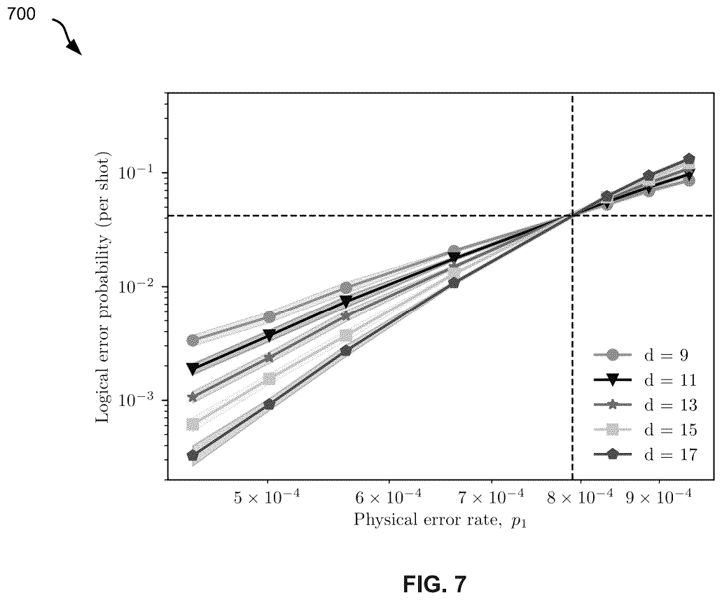

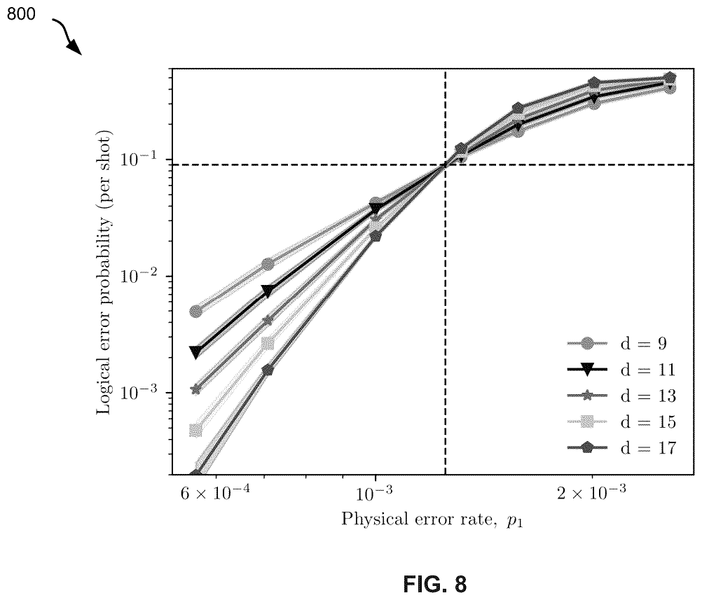

FIGS. 7-8 include a plot 700 showing l logical error probability per shot as a function of physical single qubit error rate p₁ at various distances of the standard rotated surface code syndrome measurement circuit shown in FIG. 5A and a plot 800 showing logical failure rate per shot as a function of physical error rate at various distance of the HOP syndrome measurement circuit shown in FIGS. 5B and 6. Each data point reflects either 10⁶ Monte Carlo trials, or a number of trials to observe 10⁴ logical failures, whichever is less. The threshold for the standard rotated surface code syndrome measurement circuit under the described error model is approximately 0.79×10⁻³; and the threshold for the HOP syndrome measurement circuit under the described error model is approximately 1.25×10⁻³. Shaded areas around curve represent a 99.9% confidence interval computed via binomial relative likelihood ratios.

As such, the HOP surface code appears to have an empirical threshold 1.5 times higher than that of the standard scheme. Note that our observed threshold for the standard scheme appears to be roughly an order of magnitude lower than the typically reported range of roughly 0.005 to 0.01 for the surface code under circuit-level noise. We attribute this discrepancy to our use of different failure rates for single-qubit gates, multi-qubit gates, preparations, and measurements. We empirically observe a fault-tolerant threshold for the HOP surface code that is approximately 1.5 times higher than the threshold estimated for the standard surface code. This suggests that the multi-qubit correlated error mechanisms present in the five-qubit and three-qubit gates are not strong enough to negatively affect the efficacy of this scheme at near-threshold error rates.

Here a comparison of an amount of physical resources used for either error correction scheme to implement a logical qubit encoded in a rotated surface code patch with a target logical failure rate of p_{L}=10⁻¹⁰ is discussed. This logical error rate is chosed based on a recent study indicating that roughly 10¹⁰ logical operations would be required to execute a quantum algorithm for derivative pricing in a regime where quantum advantage could be achieved. In order to compare resources, we fit curves describing logical failure rate as a function of physical error rate p₁ below threshold for various distances, and extrapolate those curves down to find the physical failure rate needed in order to achieve p_{L}=10⁻¹⁰ for each distance requiring a different number of physical qubits to implement.

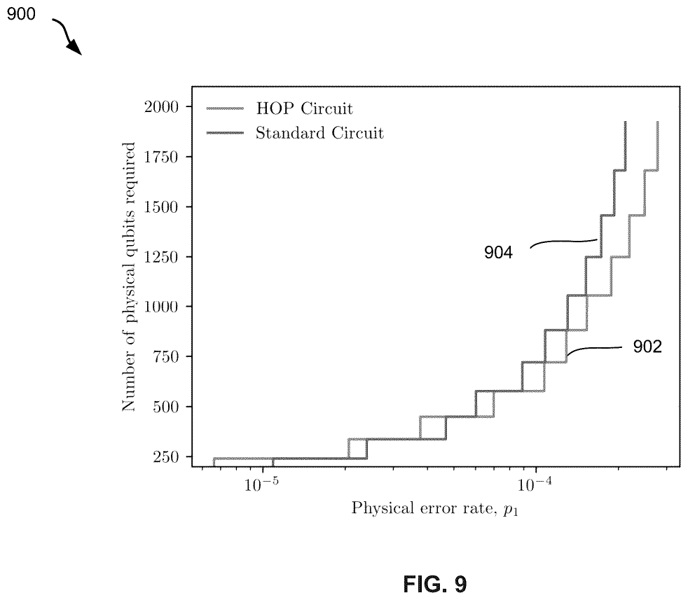

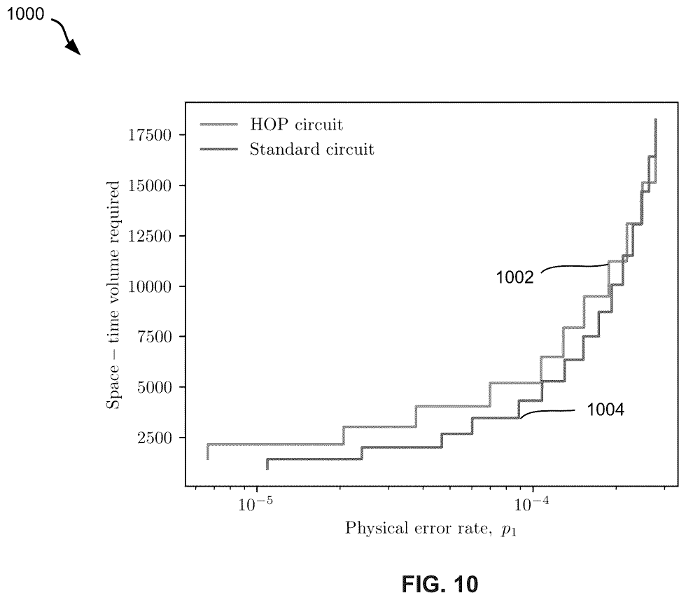

FIGS. 9-10 include a plot 900 showing the number of physical qubit devices required and a plot 1000 showing the overall space-time volume required in qubit-cycles as a function of physical error rate for both the standard syndrome measurement circuit 500 shown in FIG. 5A and the HOP syndrome measurement circuit 550 shown in FIGS. 5B and 6. In FIG. 9, curve 902 represents the number of physical qubit devices required as a function a physical error rate for the HOP syndrome measurement circuit 550; and curve 904 represents the number of physical qubit devices required as a function a physical error rate for the standard syndrome measurement circuit 500. In FIG. 10, curve 1002 represents the overall space-time volume required in qubit-cycles as a function of physical error rate for the HOP syndrome measurement circuit 550; and curve 1004 represents the overall space-time volume required in qubit-cycles as a function of physical error rate for the standard syndrome measurement circuit 500. A single error correction cycle of a logical qubit with a logical error rate p_{L}=10⁻¹⁰ is implemented. We compare resource requirements for using either scheme to implement a logical qubit with logical error rate 10⁻¹⁰ and find that in regimes of interest the HOP scheme does not require greater spacetime resources than the standard scheme and may be preferable based on hardware considerations.

One can compare estimates of two resources: physical qubit count required to implement a surface code of a distance high enough to achieve the target error rate, as well as the space-time volume (the product of physical qubit count and time steps used to complete a logical error correction cycle). In FIG. 9, one can see that at physical error rates closer to threshold, one can use a HOP surface code of smaller distance to achieve our target error rate than would be used with the standard surface code, as one would expect based on the fact that the HOP scheme yields a higher threshold. In terms of overall space-time volume, FIG. 9 shows that the two schemes are relatively evenly matched at higher physical error rates, but the standard scheme has an advantage at lower physical error rates. This is due to a single round of stabilizer check measurements using only 6 time steps in the standard scheme while the HOP scheme uses 9.

FIGS. 11A-11B are tables 1100, 1110 showing parameters and values in the numerical diagonalization of the 5-qubit interaction Hamiltonian shown in Equation (2).

In order to estimate the code distances required in order to achieve target physical error rates outside of the simulated regime, an embodiment may perform linear fits in logarithmic space to extract the logical error rate's functional dependence on the code distance d and physical error rate p₁. An example embodiment may use the simple heuristic

p_{L}(p₁, d)=c(d)p₁^{m(d)} (34)

where one may expect m(d) to be a linear function of d and c(d) to be an exponential function of d.

By performing linear regression on the data points obtained for m(d) and logc(d), one can estimate m(d) and logc(d) for d larger than one may practically simulate, and use these extrapolated values to produce FIGS. 8 and 9. It is to be appreciated that the lines of best fit for m(d) for each scheme to be

m_{HOP}(d)=0.53d−0.71 (35)

and

m_{Std}(d)=0.56d−0.406 (36)

whereas the lines of best fit for logc(d) were found to be

logc_{HOP}(d)=1.56d−3.11 937)

and

logc_{Std}(d)=1.77d−2.73. (38)

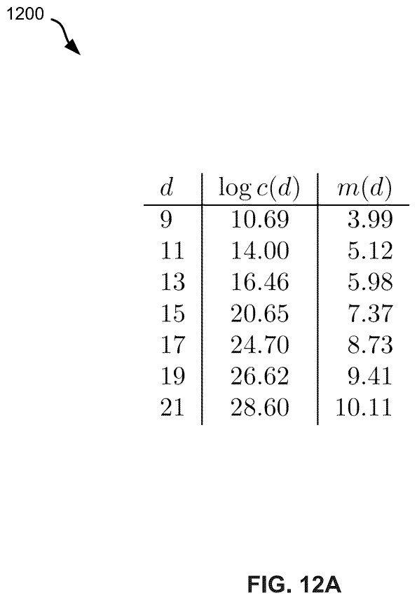

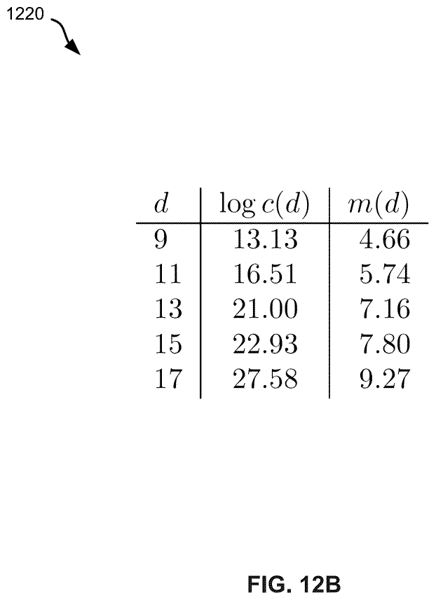

FIGS. 12A-12B include a table showing fit parameters obtained from linear regression for the HOP syndrome measurement circuit 550 shown in FIG. 5B and using the example surface code syndrome measurement process 600 shown in FIG. 6; and a table showing fit parameters obtained from linear regression for the standard syndrome measurement circuit 500 shown in FIG. 5A.

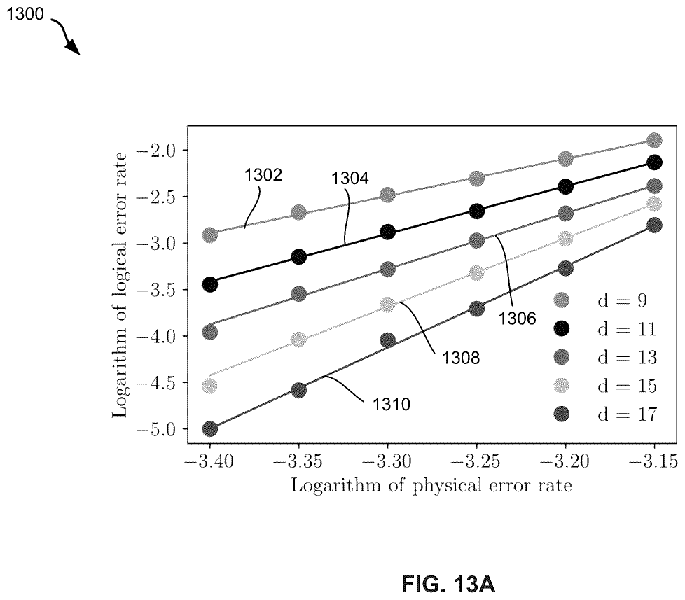

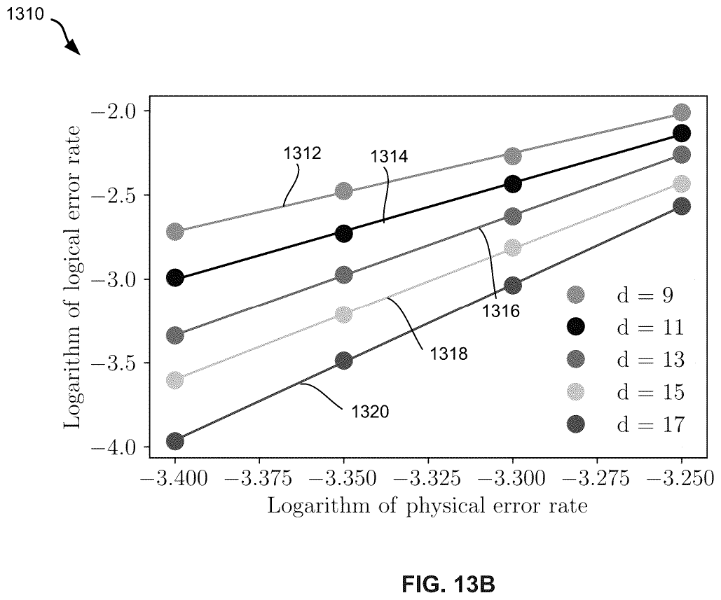

FIGS. 13A-13B include a log-log plot 1300 showing logical error rate as a function of physical error rate at various distance of the HOP syndrome measurement circuit 550 shown in FIG. 5B and a log-log plot 1320 showing logical error rate as a function of physical error rate at various distances of the standard rotated surface code syndrome measurement circuit 500 shown in FIG. 5A. A single error correction cycle of a logical qubit (as shown in the example process 600 FIG. 6) is implemented. Curves 1302, 1304, 1306, 1308, 1308 in FIG. 13A and curves 1312, 1314, 1316, 1318, 1320 in FIG. 13B correspond to a code distance d =9, 11, 13, 15, 17, respectively.

Some of the operations described in this specification can be implemented as operations performed by a data processing apparatus on data stored on one or more computer-readable storage devices or received from other sources.

The term “data-processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them.

A computer program (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program, or in multiple coordinated files (e.g., files that store one or more modules, sub programs, or portions of code). A computer program can be deployed to be executed on one computer or on multiple computers that are located at one site or distributed across multiple sites and interconnected by a communication network.

Some of the processes and logic flows described in this specification can be performed by one or more programmable processors executing one or more computer programs to perform actions by operating on input data and generating output. The processes and logic flows can also be performed by, and apparatus can also be implemented as, special purpose logic circuitry, e.g., an FPGA (field programmable gate array) or an ASIC (application specific integrated circuit).

In a general aspect, a method and a system for performing a surface code syndrome measurement in a superconducting quantum processing unit are presented.

In a first example, a method of performing a surface code syndrome measurement on a superconducting quantum processing unit includes by operation of one or more classical computing systems: causing the superconducting quantum processing unit to apply a quantum error correction code. The quantum error correction code includes a plurality of planar code patches. The plurality of planar code patches includes X-type stabilizer check patches and Z-type stabilizer check patches. Each of the X-type stabilizer check patches and the Z-type stabilizer check patches includes a stabilizer check qubit device and two or more data qubit devices of the superconducting quantum processing unit. Applying the quantum error correction code includes iteratively performing operations including twirling the two or more data qubit devices in a stabilizer check patch; and evolving the stabilizer check qubit device in the stabilizer check patch and the two or more data qubit devices in the stabilizer check patch under an interaction Hamiltonian. The interaction Hamiltonian includes a plurality of terms. Each of the plurality of terms corresponds to an interaction between the stabilizer check qubit device in the stabilizer check patch and a respective one of the two or more data qubit devices in the stabilizer check patch. Each of the terms includes a coupling strength combined with a Pauli operator applied to the stabilizer check qubit device and the Pauli operator applied to the respective one of the two or more data qubit devices.

Implementations of the first example may include one or more of the following features. Twirling the two or more data qubit devices in the stabilizer check patch includes applying random single-qubit Pauli gates on the two or more data qubit devices in the stabilizer check patch. The stabilizer check qubit device and each of the two or more data qubit devices in the stabilizer check patch are communicably coupled by a respective tunable-frequency coupler device, and the respective tunable-frequency coupler device is a flux tunable transmon qubit device.

Implementations of the first example may include one or more of the following features. The stabilizer check patch includes four data qubit devices, and the interaction Hamiltonian has a form indicative of at least

$${H}_{disp} = \frac{- ζ ( t )}{4} {\sum }_{k = 1}^{4} {σ}_{0} {σ}_{k} ,$$

where ζ(t) is a time-dependent coupling strength, a σ₀ represents the Pauli operator applied to the stabilizer check qubit device, σₖ represents the Pauli operator applied to the k^{th} data qubit device, and k is an integer. Evolving the stabilizer check qubit device and the two or more data qubit devices in the stabilizer check patch under the interaction Hamiltonian includes evolving the stabilizer check qubit device and the four data qubit devices in the stabilizer check patch under the interaction Hamiltonian with a constant coupling strength, ζ(t)=ζ₀. Evolving the stabilizer check qubit device and the two or more data qubit devices in the stabilizer check patch under the interaction Hamiltonian includes tuning the coupling strength by tuning respective flux biases in the respective tunable-frequency coupler devices in the stabilizer check patch.

Implementations of the first example may include one or more of the following features. The method includes after evolving the stabilizer check qubit device in the stabilizer check patch and the two or more data qubit devices in the stabilizer check patch under the interaction Hamiltonian, performing a qubit readout measurement on the stabilizer check qubit device. The quantum error correction scheme is based on a surface error correction code.

Implementations of the first example may include one or more of the following features. Applying the quantum error correction code in the stabilizer check patch includes after twirling the two or more data qubit devices, applying Hadamard gates on the two or more data qubit devices in the stabilizer check patch. Applying the quantum error correction code in the stabilizer check patch includes prior to evolving the stabilizer check qubit device and the two or more data qubit devices in the stabilizer check patch under the interaction Hamiltonian, preparing the stabilizer check qubit device by applying a first Hadamard gate on the stabilizer check qubit device in the stabilizer check patch; and after evolving the stabilizer check qubit device and the two or more data qubit devices in the stabilizer check patch under the interaction Hamiltonian, mapping the qubit defined by the stabilizer check qubit device by applying a second Hadamard gate on the stabilizer check qubit device in the stabilizer check patch.

Implementations of the first example may include one or more of the following features. Applying the quantum error correction code includes twirling two or more data qubit devices in a X-type stabilizer check patch; evolving a stabilizer check qubit device in the X-type stabilizer check patch and the two or more data qubit devices in the X-type stabilizer check patch under a first interaction Hamiltonian; twirling two or more data qubit devices in a Z-type stabilizer check patch; and evolving a stabilizer check qubit device in the Z-type stabilizer check patch and the two or more data qubit devices in the Z-type stabilizer check patch under a second interaction Hamiltonian. The first Hamiltonian includes first terms. Each of the first terms includes a first coupling strength combined with a Pauli-X operator applied to the stabilizer check qubit device and the Pauli-X operator applied to the respective one of the two or more data qubit devices in the X-type stabilizer check patch. The second Hamiltonian comprises second terms. Each of the second terms includes a second coupling strength combined with a Pauli-Z operator applied to the stabilizer check qubit device and the Pauli-Z operator applied to the respective one of the two or more data qubit devices in the Z-type stabilizer check patch.

In a second example, a quantum computing system includes a superconducting quantum processing unit and a control system communicably coupled to the superconducting quantum processing unit. The quantum processing unit includes a stabilizer check qubit device and two or more data qubit devices coupled to the stabilizer check qubit device through respective tunable-frequency coupler devices. The control system is operable to perform operations in the first example.

While this specification contains many details, these should not be understood as limitations on the scope of what may be claimed, but rather as descriptions of features specific to particular examples. Certain features that are described in this specification or shown in the drawings in the context of separate implementations can also be combined. Conversely, various features that are described or shown in the context of a single implementation can also be implemented in multiple implementations separately or in any suitable sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single product or packaged into multiple products.

A number of embodiments have been described. Nevertheless, it will be understood that various modifications can be made. Accordingly, other embodiments are within the scope of the following claims.

What is claimed is:

1. A method of performing a surface code syndrome measurement on a superconducting quantum processing unit, the method comprising, by operation of one or more classical computing systems:
causing the superconducting quantum processing unit to apply a quantum error correction code, wherein the quantum error correction code comprises a plurality of planar code patches, the plurality of planar code patches comprises X-type stabilizer check patches and Z-type stabilizer check patches, each of the X-type stabilizer check patches and the Z-type stabilizer check patches comprises a stabilizer check qubit device and two or more data qubit devices of the superconducting quantum processing unit, wherein applying the quantum error correction code comprises iteratively performing operations comprising:
twirling the two or more data qubit devices in a stabilizer check patch; and
evolving the stabilizer check qubit device in the stabilizer check patch and the two or more data qubit devices in the stabilizer check patch under an interaction Hamiltonian, the interaction Hamiltonian comprising a plurality of terms, each of the plurality of terms corresponding to an interaction between the stabilizer check qubit device in the stabilizer check patch and a respective one of the two or more data qubit devices in the stabilizer check patch, each of the terms comprising a coupling strength combined with a Pauli operator applied to the stabilizer check qubit device and the Pauli operator applied to the respective one of the two or more data qubit devices.

2. The method of claim 1, wherein twirling the two or more data qubit devices in the stabilizer check patch comprises:
applying random single-qubit Pauli gates on data qubits defined by the two or more data qubit devices in the stabilizer check patch.

3. The method of claim 1, wherein the stabilizer check qubit device and each of the two or more data qubit devices in the stabilizer check patch are communicably coupled by a respective tunable-frequency coupler device, and the respective tunable-frequency coupler device is a flux tunable transmon qubit device.

4. The method of claim 3, wherein the stabilizer check patch comprises four data qubit devices, and the interaction Hamiltonian has a form indicative of at least:
$${H}_{disp} = \frac{- ζ ( t )}{4} {\sum }_{k = 1}^{4} {σ}_{0} {σ}_{k}$$
where ζ(t) is a time-dependent coupling strength, σ₀ represents the Pauli operator applied to the stabilizer check qubit device, σₖ represents the Pauli operator applied to the k^{th} data qubit device, and k is an integer.

5. The method of claim 4, wherein evolving the stabilizer check qubit device and the two or more data qubit devices in the stabilizer check patch under the interaction Hamiltonian comprises:
evolving the stabilizer check qubit device and the four data qubit devices in the stabilizer check patch under the interaction Hamiltonian with a constant coupling strength, ζ(t)=ζ₀.

6. The method of claim 4, wherein evolving the stabilizer check qubit device and the two or more data qubit devices in the stabilizer check patch under the interaction Hamiltonian comprises:
tuning the coupling strength by tuning respective flux biases in the respective tunable-frequency coupler devices in the stabilizer check patch.

7. The method of claim 1, comprising:
after evolving the stabilizer check qubit device in the stabilizer check patch and the two or more data qubit devices in the stabilizer check patch under the interaction Hamiltonian, performing a qubit readout measurement on the stabilizer check qubit device.

8. The method of claim 1, wherein the quantum error correction scheme is based on a surface error correction code.

9. The method of claim 1, wherein applying the quantum error correction code in the stabilizer check patch comprises:
after twirling the two or more data qubit devices, applying Hadamard gates on the two or more data qubit devices in the stabilizer check patch.

10. The method of claim 1, wherein applying the quantum error correction code in the stabilizer check patch comprises:
prior to evolving the stabilizer check qubit device and the two or more data qubit devices in the stabilizer check patch under the interaction Hamiltonian, preparing the stabilizer check qubit device by applying a first Hadamard gate on the stabilizer check qubit device in the stabilizer check patch; and
after evolving the stabilizer check qubit device and the two or more data qubit devices in the stabilizer check patch under the interaction Hamiltonian, mapping the qubit defined by the stabilizer check qubit device by applying a second Hadamard gate on the stabilizer check qubit device in the stabilizer check patch.

11. The method of claim 1, wherein applying the quantum error correction code comprises:
twirling two or more data qubit devices in a X-type stabilizer check patch;
evolving a stabilizer check qubit device in the X-type stabilizer check patch and the two or more data qubit devices in the X-type stabilizer check patch under a first interaction Hamiltonian, wherein the first Hamiltonian comprises first terms, each of the first terms comprises a first coupling strength combined with a Pauli-X operator applied to the stabilizer check qubit device and the Pauli-X operator applied to the respective one of the two or more data qubit devices in the X-type stabilizer check patch;
twirling two or more data qubit devices in a Z-type stabilizer check patch; and
evolving a stabilizer check qubit device in the Z-type stabilizer check patch and the two or more data qubit devices in the Z-type stabilizer check patch under a second interaction Hamiltonian, wherein the second Hamiltonian comprises second terms, each of the second terms comprises a second coupling strength combined with a Pauli-Z operator applied to the stabilizer check qubit device and the Pauli-Z operator applied to the respective one of the two or more data qubit devices in the Z-type stabilizer check patch.

12. A quantum computing system comprising:
a superconducting quantum processing unit comprising a stabilizer check qubit device and two or more data qubit devices coupled to the stabilizer check qubit device through respective tunable-frequency coupler devices; and
a control system communicably coupled to the superconducting quantum processing unit and operable to cause the superconducting quantum processing unit to apply a quantum error correction code, wherein the quantum error correction code comprises a plurality of planar code patches, the plurality of planar code patches comprises X-type stabilizer check patches and Z-type stabilizer check patches, each of the X-type stabilizer check patches and the Z-type stabilizer check patches comprises a stabilizer check qubit device and two or more data qubit devices of the superconducting quantum processing unit, wherein applying the quantum error correction code comprises iteratively performing operations comprising:
twirling the two or more data qubit devices in a stabilizer check patch; and
evolving the stabilizer check qubit device in the stabilizer check patch and the two or more data qubit devices in the stabilizer check patch under an interaction Hamiltonian, the interaction Hamiltonian comprising a plurality of terms, each of the plurality of terms corresponding to an interaction between the stabilizer check qubit device in the stabilizer check patch and a respective one of the two or more data qubit devices in the stabilizer check patch, each of the terms comprising a coupling strength combined with a Pauli operator applied to the stabilizer check qubit device and the Pauli operator applied to the respective one of the two or more data qubit devices.

13. The quantum computing system of claim 12, wherein twirling the two or more data qubit devices in the stabilizer check patch comprises:
applying random single-qubit Pauli gates on data qubits defined by the two or more data qubit devices in the stabilizer check patch.

14. The quantum computing system of claim 12, wherein the stabilizer check qubit device and each of the two or more data qubit devices in the stabilizer check patch are communicably coupled by a respective tunable-frequency coupler device, and the respective tunable-frequency coupler device is a flux tunable transmon qubit device.

15. The quantum computing system of claim 14, wherein the stabilizer check patch comprises four data qubit devices, and the interaction Hamiltonian has a form indicative of at least:
$${H}_{disp} = \frac{- ζ ( t )}{4} {\sum }_{k = 1}^{4} {σ}_{0} {σ}_{k}$$
where ζ(t) is a time-dependent coupling strength, σ₀ represents the Pauli operator applied to the stabilizer check qubit device, σₖ represents the Pauli operator applied to the k^{th} data qubit device, and k is an integer.

16. The quantum computing system of claim 15, wherein evolving the stabilizer check qubit device and the two or more data qubit devices in the stabilizer check patch under the interaction Hamiltonian comprises:
evolving the stabilizer check qubit device and the four data qubit devices in the stabilizer check patch under the interaction Hamiltonian with a constant coupling strength, ζ(t)=ζ₀.

17. The quantum computing system of claim 15, wherein evolving the stabilizer check qubit device and the two or more data qubit devices in the stabilizer check patch under the interaction Hamiltonian comprises:
tuning the coupling strength by tuning respective flux biases in the respective tunable-frequency coupler devices in the stabilizer check patch.

18. The quantum computing system of claim 12, wherein the operations comprise:
after evolving the stabilizer check qubit device in the stabilizer check patch and the two or more data qubit devices in the stabilizer check patch under the interaction Hamiltonian, performing a qubit readout measurement on the stabilizer check qubit device.

19. The quantum computing system of claim 12, wherein applying the quantum error correction code in the stabilizer check patch comprises:
after twirling the two or more data qubit devices, applying Hadamard gates on the two or more data qubit devices in the stabilizer check patch.

20. The quantum computing system of claim 12, wherein applying the quantum error correction code in the stabilizer check patch comprises:
prior to evolving the stabilizer check qubit device and the two or more data qubit devices in the stabilizer check patch under the interaction Hamiltonian, preparing the stabilizer check qubit device by applying a first Hadamard gate on the stabilizer check qubit device in the stabilizer check patch; and
after evolving the stabilizer check qubit device and the two or more data qubit devices in the stabilizer check patch under the interaction Hamiltonian, mapping the qubit defined by the stabilizer check qubit device by applying a second Hadamard gate on the stabilizer check qubit device in the stabilizer check patch.
